(19) United States
(12) Patent Application Publication
(10) Pub. No.: US 2026/0271563 A1
(43) Pub. Date: Sep. 10, 2026

(54) DISPLAY PANEL AND ELECTRONIC APPARATUS INCLUDING THE SAME

(71) Applicant: Samsung Display Co., Ltd., Yongin-si (KR)

(72) Inventors: Sunghwan KIM, Yongin-si (KR); Mihae KIM, Yongin-si (KR); Huigyeong YUN, Yongin-si (KR)

(73) Assignee: Samsung Display Co., Ltd., Yongin-si (KR)

(21) Appl. No.: 19/556,734

(22) Filed: Mar. 4, 2026

(30) Foreign Application Priority Data
Mar. 6, 2025 (KR) 10-2025-0029207

(51) Int. Cl. H10K 59/131; H10K 59/121

(52) U.S. Cl. CPC H10K 59/131; H10K 59/1213

(57) ABSTRACT

Provided are a display panel including a driving transistor including a driving semiconductor layer, a first switching transistor including a first switching semiconductor layer, a light-emitting diode connected to the driving transistor through the first switching transistor, a first conductive layer overlapping a channel region of the driving semiconductor layer, an electrode voltage line including a main portion overlapping the first conductive layer and a branch portion extending from the main portion in a first direction, and a driving voltage line connected to the electrode voltage line, wherein the driving and the first switching semiconductor layers are connected as a single semiconductor pattern, and a portion of the single semiconductor pattern between the channel region of the driving semiconductor layer and a channel region of the first switching semiconductor layer does not overlap the branch portion of the electrode voltage line.

### CROSS-REFERENCE TO RELATED APPLICATION

This application is based on and claims priority under 35 U.S.C. §119 to Korean Patent Application No. 10-2025-0029207, filed on March 6, 2025, in the Korean Intellectual Property Office, the disclosure of which is incorporated by reference herein in its entirety.

### BACKGROUND

### Field

One or more embodiments relate to a display panel and an electronic apparatus including the display panel, and more particularly, to a display panel capable of displaying high-quality images, and an electronic apparatus including the display panel.

### Description of the Related Art

Display panels are used in various electronic apparatuses. To display high-quality images by increasing resolution, the size of pixels is decreased, and accordingly, it is necessary to arrange various electronic elements in a narrow area.

### SUMMARY

However, as such display panels of the related art and electronic apparatuses including the display panels have higher resolution, various transistors, wirings, and electrodes need to be in a relatively narrow space, resulting in the occurrence of unnecessary electrical interference.

One or more embodiments include a display panel capable of displaying high-quality images, and an electronic apparatus including the display panel. However, the embodiments are examples, and the scope of the disclosure is not limited thereto.

Additional aspects will be set forth in part in the description which follows and, in part, will be apparent from the description, or may be learned by practice of the presented embodiments of the disclosure.

According to one or more embodiments, a display panel includes a substrate, a driving transistor including a driving semiconductor layer on the substrate, a first switching transistor including a first switching semiconductor layer, a light-emitting diode connected to the driving transistor through the first switching transistor, a first conductive layer overlapping a channel region of the driving semiconductor layer in plan view and including a driving gate electrode of the driving transistor, an electrode voltage line on the first conductive layer and including a main portion and a branch portion, the main portion overlapping the first conductive layer in plan view, and the branch portion extending from the main portion in a first direction, and a driving voltage line extending in a second direction intersecting the first direction, and connected to the electrode voltage line, wherein the driving semiconductor layer and the first switching semiconductor layer are integrally connected as a single semiconductor pattern, and a portion of the single semiconductor pattern between the channel region of the driving semiconductor layer and a channel region of the first switching semiconductor layer does not overlap the branch portion of the electrode voltage line in plan view.

The display panel may further include a first connection electrode connected to the first switching semiconductor layer and being, in a cross-sectional view, between the first switching semiconductor layer and a pixel electrode of the light-emitting diode, wherein, in plan view, the branch portion of the electrode voltage line may overlap a portion of the first switching semiconductor layer that is between the channel region of the first switching semiconductor layer and a contact portion between the first switching semiconductor layer and the first connection electrode.

A portion of the first connection electrode may overlap the portion of the first switching semiconductor layer and a portion of the branch portion of the electrode voltage line in plan view.

The display panel may further include an emission control line connected to a gate electrode of the first switching transistor, wherein each of a capacitance between the emission control line and the first connection electrode and a capacitance between the emission control line and the portion of the first switching semiconductor layer may be in a range of about 0 femto-Farad (fF) to about 1.5 fF.

In plan view, the emission control line may not overlap the portion of the first switching semiconductor layer.

The display panel may further include a lower conductive layer below the driving semiconductor layer and including a main portion and a first branch portion, the main portion of the lower conductive layer overlapping the first conductive layer in plan view, and the first branch portion of the lower conductive layer extending from the main portion of the lower conductive layer in the first direction, wherein the first branch portion of the lower conductive layer may overlap the branch portion of the electrode voltage line in plan view, and the portion of the first switching semiconductor layer may be, in a cross-sectional view, between the first branch portion of the lower conductive layer and the branch portion of the electrode voltage line.

The display panel may further include a second switching semiconductor layer in a different layer from the driving semiconductor layer, and a bridge electrode connecting the first conductive layer and the second switching semiconductor layer.

The lower conductive layer may further include a second branch portion extending from the main portion of the lower conductive layer in the second direction, wherein the bridge electrode may overlap the second branch portion in plan view, and the driving voltage line may overlap the bridge electrode in plan view.

The lower conductive layer may have a constant voltage level.

The display panel may further include a second connection electrode being, in a cross-sectional view, between the electrode voltage line and the driving voltage line, wherein the second connection electrode may be connected to the electrode voltage line through a contact hole formed in an insulating layer between the electrode voltage line and the second connection electrode, and the driving voltage line may be connected to the second connection electrode through a contact hole formed in an insulating layer between the driving voltage line and the second connection electrode, and the second connection electrode may extend in the first direction, and may not overlap the first portion of the single semiconductor pattern in plan view.

According to one or more embodiments, an electronic apparatus includes a substrate, a first semiconductor pattern including silicon, the first semiconductor pattern including a driving semiconductor layer of a driving transistor and a first switching semiconductor layer of a first switching transistor, a lower conductive layer between the substrate and the first semiconductor pattern, a first conductive layer on the first semiconductor pattern and overlapping a channel region of the driving semiconductor layer in plan view, an electrode voltage line on the first conductive layer and including a main portion and a branch portion, the main portion overlapping the first conductive layer in plan view, and the branch portion extending from the main portion in a first direction, a driving voltage line extending in a second direction intersecting the first direction, and connected to the electrode voltage line, a first connection electrode connected to the first switching semiconductor layer, and a light-emitting diode including a pixel electrode on the first connection electrode and connected to the first connection electrode, an emission layer on the pixel electrode, and a common electrode on the emission layer, wherein a first portion of the first semiconductor pattern between the channel region of the driving semiconductor layer and a channel region of the first switching semiconductor layer does not overlap the branch portion of the electrode voltage line in plan view.

In plan view, the branch portion of the electrode voltage line may overlap a second portion of the first semiconductor pattern that is between the channel region of the first switching semiconductor layer and a contact portion between the first switching semiconductor layer and the first connection electrode.

A portion of the first connection electrode may overlap the second portion of the first semiconductor pattern and a portion of the branch portion of the electrode voltage line in plan view.

The electronic apparatus may further include an emission control line connected to a gate electrode of the first switching transistor, wherein, in plan view, the emission control line may not overlap the second portion of the first semiconductor pattern.

A capacitance between the emission control line and the first connection electrode may be in a range of about 0 femto-Farad (fF) to about 1.5 fF, and a capacitance between the emission control line and the second portion of the first semiconductor pattern may be in a range of about 0 fF to about 1.5 fF.

The lower conductive layer may include a main portion overlapping the first conductive layer in plan view and a first branch portion extending from the main portion of the lower conductive layer in the first direction, wherein the first branch portion of the lower conductive layer may overlap the branch portion of the electrode voltage line in plan view, and the second portion of the first semiconductor pattern may be, in a cross-sectional view, between the first branch portion of the lower conductive layer and the branch portion of the electrode voltage line.

The electronic apparatus may further include a second semiconductor pattern in a different layer from the first semiconductor pattern and including an oxide semiconductor, and a bridge electrode connecting the first conductive layer and the second semiconductor pattern.

The lower conductive layer may include a main portion overlapping the first conductive layer in plan view and a second branch portion extending from the main portion of the lower conductive layer in the second direction, wherein the bridge electrode may overlap the second branch portion of the lower conductive layer in plan view, and the driving voltage line may overlap the bridge electrode in plan view.

The lower conductive layer may have a constant voltage level.

The electronic apparatus may further include a second connection electrode being, in a cross-sectional view, between the electrode voltage line and the driving voltage line, wherein the second connection electrode may be connected to the electrode voltage line through a contact hole formed in an insulating layer between the electrode voltage line and the second connection electrode, and the driving voltage line may be connected to the second connection electrode through a contact hole formed in an insulating layer between the driving voltage line and the second connection electrode, and the second connection electrode may extend in the first direction, and may not overlap the first portion of the first semiconductor pattern in plan view.

Other aspects, features, and advantages than those described above will become apparent from the detailed descriptions, claims, and drawings for carrying out the following disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A is a block diagram of an electronic apparatus according to an embodiment; FIG. 1B shows schematic diagrams of electronic apparatuses according to various embodiments;

FIG. 2 is a schematic plan view of a display panel;

FIGS. 3 and 4 are schematic enlarged conceptual diagrams of region A of the display panel of FIG. 2;

FIG. 5 is an equivalent circuit diagram of a pixel circuit electrically connected to a light-emitting diode of a display panel, according to an embodiment;

FIG. 6 is a schematic plan view showing positions of transistors and capacitors corresponding to pixels included in a display panel, according to an embodiment;

FIG. 7 is a cross-sectional view of a pixel circuit of a display panel and a light-emitting diode electrically connected to the pixel circuit, according to an embodiment;

FIGS. 8 to 15 are schematic plan views showing components, such as transistors and capacitors, of the display panel shown in FIG. 6 for each layer; and

FIG. 16 is an enlarged cross-sectional view of a portion of a display panel according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b and c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure, and methods of achieving the same will become apparent with reference to the drawings and embodiments described in detail below. The disclosure may, however, be embodied in many different forms and should not be construed as being limited to the embodiments set forth herein.

Hereinafter, embodiments of the disclosure will be described in detail with reference to the accompanying drawings, and in the description with reference to the drawings, the same or corresponding components are indicated by the same reference numerals, and redundant descriptions thereof are omitted.

In the following embodiments, when a component, such as a layer, a film, a region, or a plate, is referred to as being “on” another component, the component can be directly on the other component, or intervening components may be present therebetween. In addition, sizes of components in the drawings may be exaggerated or reduced for descriptive convenience. In other words, since sizes and thicknesses of components in the drawings are arbitrarily illustrated for descriptive convenience, the following embodiments are not limited thereto.

In the following embodiments, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the following embodiments, while terms such as “first” and “second” may be used to describe various components, these components should not be limited by these terms. These terms are only used to distinguish one component from another.

In the following embodiments, terms such as “include,” “comprise,” and “have” specify the presence of stated features or components, but do not preclude the presence or addition of one or more other features or components.

In the following embodiments, when a layer, region, or component is referred to as being “connected to” another layer, region, or component, it can be directly or indirectly connected to the other layer, region, or component. For example, intervening layers, regions, or components may be present. For example, when a layer, region, or component is referred to as being “electrically connected to” or “electrically coupled to” another layer, region, or component, it can be directly or indirectly electrically connected or coupled to the other layer, region, or component. For example, intervening layers, regions, or components may be present.

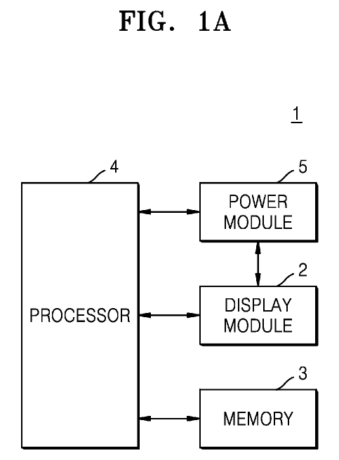

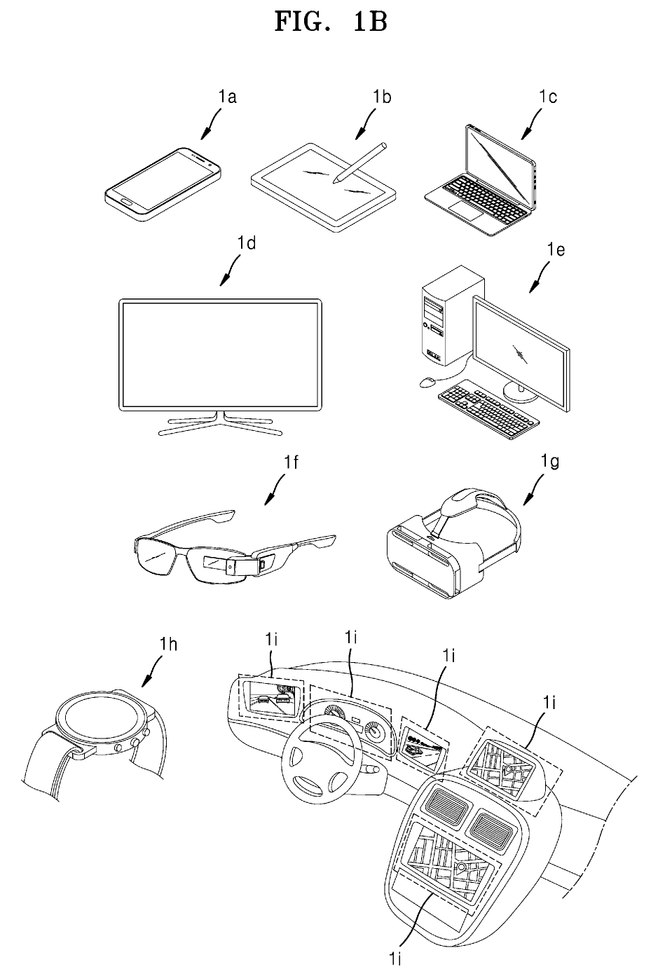

FIG. 1A is a block diagram of an electronic apparatus 1 according to an embodiment. FIG. 1B shows schematic diagrams of electronic apparatuses according to various embodiments.

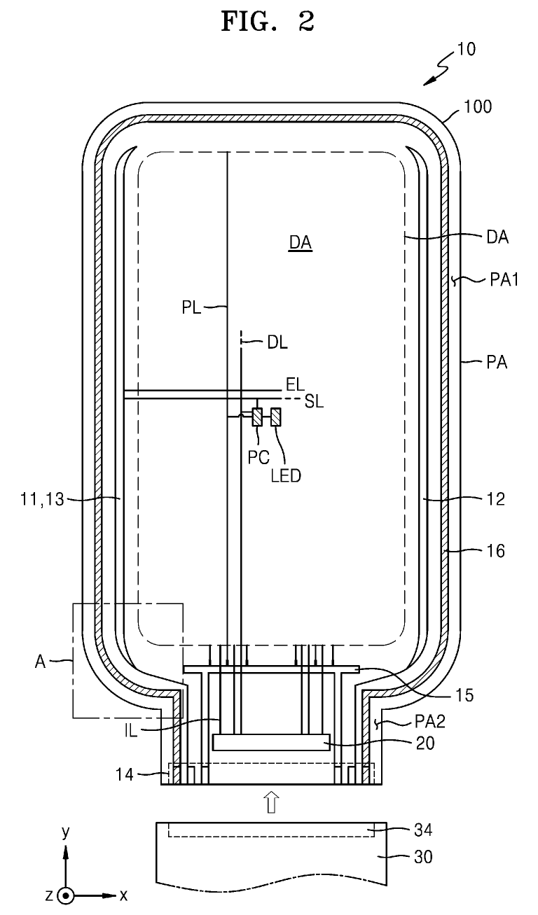

Referring to FIG. 1A, the electronic apparatus 1 according to an embodiment may include a display module 2, a memory 3, a processor 4, and a power module 5. The display module 2 may include a display panel 10 (see FIG. 2) according to an embodiment. In some embodiments, the display module 2 may include the display panel 10 (see FIG. 2), a gate driver, and a data driver. In an embodiment, the display panel 10 (see FIG. 2), the gate driver, and/or the data driver may be formed together in a process of forming the display panel 10 (see FIG. 2). For example, the display panel 10 (see FIG. 2) may correspond to the display module 2. In an embodiment, the gate driver and/or the data driver may be arranged on the display panel 10 (see FIG. 2), and may be electrically connected to the display panel 10 (see FIG. 2) through a bonding structure.

The processor 4 may include at least one of a central processing unit (CPU), an application processor (AP), a graphics processing unit (GPU), a communication processor (CP), an image signal processor (ISP), and a controller.

The memory 3 may store data information for the operation of the processor 4 or the display module 2. When the processor 4 executes an application stored in the memory 3, an image data signal and/or an input control signal may be transmitted to the display module 2, and the display module 2 may process the received signal and output image information through a display screen.

The power module 5 may include a power supply module, such as a power adapter or a battery device, and a power conversion module that converts power supplied by the power supply module to generate voltages or currents for the operation of the electronic apparatus 1.

At least one of the components of the electronic apparatus 1 described above may be included (or integrated) in a display device including the display module 2. For example, some of individual modules functionally included (or integrated) in one module may be included in the display device, while others may be formed separately from the display device. For example, the display device may include only the display module 2, while the processor 4, the memory 3, and the power module 5 may be formed in the form of other devices in the electronic apparatus 1 other than the display device.

Referring to FIG. 1B, electronic apparatuses according to embodiments may include not only electronic apparatuses for displaying images, such as a smartphone 1a, a tablet personal computer (PC) 1b, a laptop 1c, a television (TV) 1d, and a desktop monitor 1e, but also wearable electronic apparatuses including display modules, such as smart glasses 1f, a head-mounted display 1g, and a smart watch 1h, and vehicle electronic apparatuses 1i including display modules, such as an instrument panel of a vehicle, a center information display (CID) arranged on a center fascia and/or a dashboard of a vehicle, and a room mirror display.

FIG. 2 is a schematic plan view of the display panel 10. As shown in FIG. 2, the display panel 10 may include a substrate 100. Various components forming the display panel 10 may be arranged on the substrate 100.

The substrate 100 may include glass, ceramic, metal, or polymer resin. The substrate 100 may include, for example, polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layer structure including at least two layers including the above polymer resin and an inorganic layer between the at least two layers. In another example, the substrate 100 may have a structure in which a layer including the above polymer resin and an inorganic layer are alternately stacked. The inorganic layer may include, for example, silicon oxide, silicon nitride, and/or silicon oxynitride.

Pixels may be arranged in a display area DA, which provides an image by using light emitted from the pixels. Each pixel may include a light-emitting diode LED, which is electrically connected to a pixel circuit PC. The pixel circuit PC and the light-emitting diode LED may be arranged in the display area DA. For illustrative convenience, FIG. 2 shows that the pixel circuit PC and the light-emitting diode LED are positioned in side-by-side configuration, but in implementation, the pixel circuit PC and the light-emitting diode LED may at least partially overlap each other. For example, the light-emitting diode LED may be arranged on the pixel circuit PC.

A gate driving circuit, a pad 14, a power supply wiring 15, and a common voltage supply wiring 16 may be arranged in a peripheral area PA. The gate driving circuit may include, for example, a first scan driving circuit 11, a second scan driving circuit 12, and/or an emission control driving circuit 13. A first scan driving circuit 11, a second scan driving circuit 12, and an emission control driving circuit 13 may be positioned in a first peripheral area PA1.

The first scan driving circuit 11 may provide a scan signal to the pixel circuit PC through a gate line SL. The second scan driving circuit 12 may be arranged opposite to the first scan driving circuit 11 with the display area DA therebetween. Some of the pixel circuits PC arranged in the display area DA may be electrically connected to the first scan driving circuit 11, and the others may be connected to the second scan driving circuit 12. In some cases, the second scan driving circuit 12 may be omitted.

The emission control driving circuit 13 may be arranged on a side of the display area DA, like the first scan driving circuit 11. The emission control driving circuit 13 may provide an emission control signal to a pixel circuit PC through an emission control line EL. FIG. 2 shows that the emission control driving circuit 13 is arranged only on a side (or single side) of the display area DA, but the disclosure is not limited thereto. For example, the display panel 10 may include emission control driving circuits 13 respectively arranged on a side and another side of the display area DA. In another example, the first scan driving circuit 11 may be arranged on a side of the display area DA, and the emission control driving circuit 13 may be arranged on the other side of the display area DA.

The pad 14 may be arranged in a second peripheral area PA2 of the substrate 100. The pad 14 may be exposed without being covered by an insulating layer, and may be electrically connected to a display circuit board 30. A pad 34 of the display circuit board 30 may be electrically connected to the pad 14 of the display panel 10.

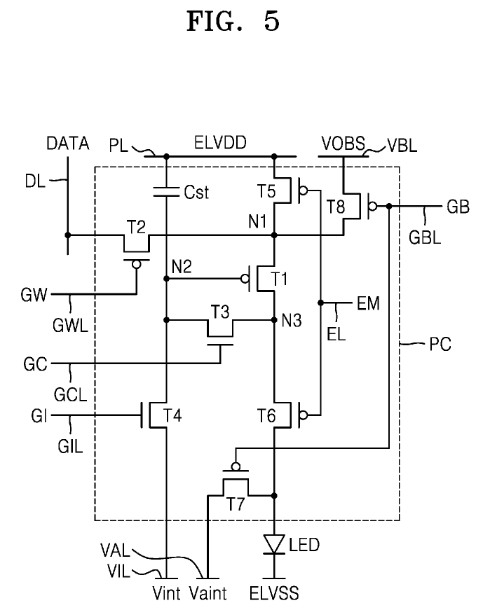

The display circuit board 30 may transmit a signal or power from a controller to the display panel 10. A control signal generated by the controller may be transmitted to each gate driving circuit through the display circuit board 30. For example, the controller may provide a driving voltage ELVDD (see FIG. 5) and a common voltage ELVSS (see FIG. 5) to the power supply wiring 15 and the common voltage supply wiring 16, respectively. The driving voltage ELVDD may be provided to each pixel circuit PC through a driving voltage line PL connected to the power supply wiring 15, and the common voltage ELVSS may be provided to a common electrode of the light-emitting diode LED connected to the common voltage supply wiring 16. The power supply wiring 15 may extend in a first direction (e.g., x-axis direction). The common voltage supply wiring 16 may have a loop shape with a side open (or single side open), and may partially surround the display area DA.

A data signal generated by a data driver 20 may be transmitted to the pixel circuit PC through an input line IL and a data line DL that is electrically connected to the input line IL.

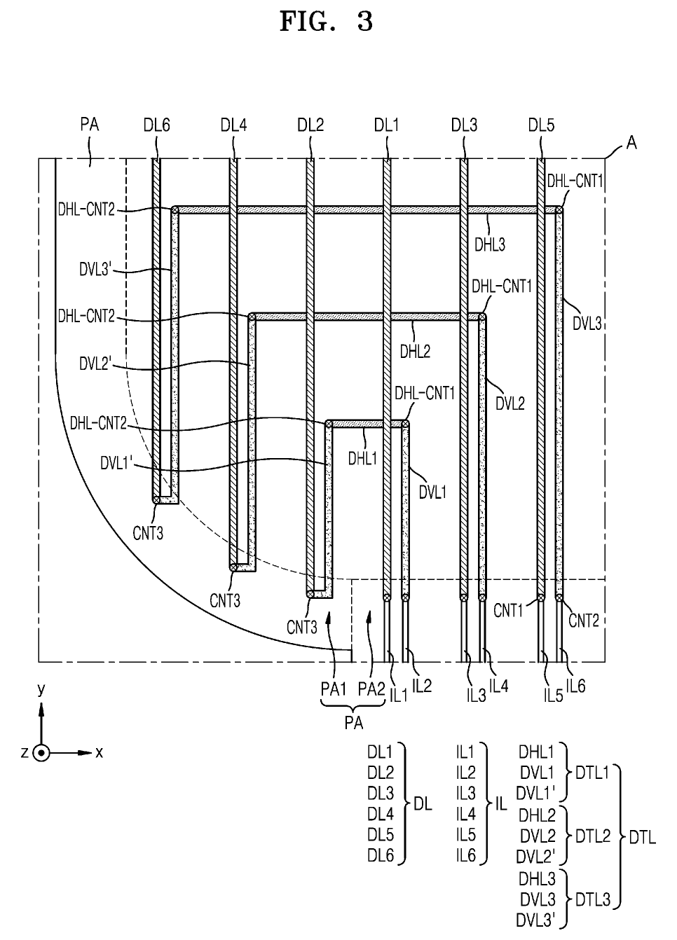

FIG. 3 is a schematic enlarged diagram of region A of the display panel 10 of FIG. 2. As illustrated in FIG. 3, the data line DL extending in a second direction (e.g., y-axis direction) may be arranged in the display area DA, and the input line IL may be arranged in the peripheral area PA. The input line IL may transmit a data signal of the data driver 20 to the data line DL. For illustrative convenience, FIG. 3 shows that the data line DL includes a first data line DL1, a second data line DL2, a third data line DL3, a fourth data line DL4, a fifth data line DL5, and a sixth data line DL6, and the input line IL includes a first input line IL1, a second input line IL2, a third input line IL3, a fourth input line IL4, a fifth input line IL5, and a sixth input line IL6, but embodiments are not limited thereto. For example, the number of data lines DL and the number of input lines IL may vary.

Some of the data lines DL may be connected (e.g., directly connected) to the corresponding input lines IL, respectively, and others of the data lines DL may be electrically connected to the corresponding input lines IL, respectively, through data transmission lines DTL.

The first data line DL1, the third data line DL3, and the fifth data line DL5 may receive data signals from the first input line IL1, the third input line IL3, and the fifth input line IL5, respectively. The first data line DL1, the third data line DL3, and the fifth data line DL5 may be electrically connected to the first input line IL1, the third input line IL3, and the fifth input line IL5, respectively. Each of the first data line DL1, the third data line DL3, and the fifth data line DL5 may be integrated to form a single body with a corresponding one of the first input line IL1, the third input line IL3, and the fifth input line IL5. In another example, each of the first data line DL1, the third data line DL3, and the fifth data line DL5 may be electrically connected to a corresponding one of the first input line IL1, the third input line IL3, and the fifth input line IL5 through a first contact hole CNT1, as shown in FIG. 3.

The second data line DL2, the fourth data line DL4, and the sixth data line DL6 may be electrically connected to the second input line IL2, the fourth input line IL4, and the sixth input line IL6 through a first data transmission line DTL1, a second data transmission line DTL2, and a third data transmission line DTL3, respectively. For example, the second input line IL2 may be electrically connected to the second data line DL2 through the first data transmission line DTL1, the fourth input line IL4 may be electrically connected to the fourth data line DL4 through the second data transmission line DTL2, and the sixth input line IL6 may be electrically connected to the sixth data line DL6 through the third data transmission line DTL3.

Most of each of the first data transmission line DTL1, the second data transmission line DTL2, and the third data transmission line DTL3 may be positioned in the display area DA. One end portion of each of the first data transmission line DTL1, the second data transmission line DTL2, and the third data transmission line DTL3 may be electrically connected to a corresponding one of the second input line IL2, the fourth input line IL4, and the sixth input line IL6 through a second contact hole CNT2. The other end portion of each of the first data transmission line DTL1, the second data transmission line DTL2, and the third data transmission line DTL3 may be electrically connected to a corresponding one of the second data line DL2, the fourth data line DL4, and the sixth data line DL6 through a third contact hole CNT3. FIG. 3 shows that the second contact hole CNT2 and the third contact hole CNT3 are positioned in the peripheral area PA, but the disclosure is not limited thereto. For example, the second contact hole CNT2 and/or the third contact hole CNT3 may be positioned in the display area DA.

The first data transmission line DTL1 may include a first horizontal connection line DHL1, a first vertical connection line DVL1, and a first additional vertical connection line DVL1’, the second data transmission line DTL2 may include a second horizontal connection line DHL2, a second vertical connection line DVL2, and a second additional vertical connection line DVL2’, and the third data transmission line DTL3 may include a third horizontal connection line DHL3, a third vertical connection line DVL3, and a third additional vertical connection line DVL3’. The first horizontal connection line DHL1, the second horizontal connection line DHL2, and the third horizontal connection line DHL3 may extend substantially in the first direction (e.g., x-axis direction). The first vertical connection line DVL1, the second vertical connection line DVL2, the third vertical connection line DVL3, the first additional vertical connection line DVL1’, the second additional vertical connection line DVL2’, and the third additional vertical connection line DVL3’ may extend substantially in the second direction (e.g., y-axis direction), and may be substantially parallel to the data line DL.

Each of the second input line IL2, the fourth input line IL4, and the sixth input line IL6 may be electrically connected to a corresponding one of the first vertical connection line DVL1, the second vertical connection line DVL2, and the third vertical connection line DVL3 through the second contact hole CNT2, and each of the second data line DL2, the fourth data line DL4, and the sixth data line DL6 may be electrically connected to a corresponding one of the first additional vertical connection line DVL1’, the second additional vertical connection line DVL2’, and the third additional vertical connection line DVL3’ through the third contact hole CNT3. Each of the first horizontal connection line DHL1, the second horizontal connection line DHL2, and the third horizontal connection line DHL3 may be electrically connected to a corresponding one of the first vertical connection line DVL1, the second vertical connection line DVL2, and the third vertical connection line DVL3 through a first connection contact hole DHL-CNT1, and may be electrically connected to a corresponding one of the first additional vertical connection line DVL1’, the second additional vertical connection line DVL2’, and the third additional vertical connection line DVL3’ through a second connection contact hole DHL-CNT2.

The first vertical connection line DVL1, the second vertical connection line DVL2, the third vertical connection line DVL3, the first additional vertical connection line DVL1’, the second additional vertical connection line DVL2’, and the third additional vertical connection line DVL3’ may be arranged on the same first layer, and the first horizontal connection line DHL1, the second horizontal connection line DHL2, and the third horizontal connection line DHL3 may be arranged on a second layer that is different from the first layer. When certain components are referred to as being arranged on the same layer, the components may be simultaneously formed using the same material through the same mask process.

As described above, FIG. 3 shows that the first data transmission line DTL1 includes the first horizontal connection line DHL1, the first vertical connection line DVL1, and the first additional vertical connection line DVL1’, the second data transmission line DTL2 includes the second horizontal connection line DHL2, the second vertical connection line DVL2, and the second additional vertical connection line DVL2’, and the third data transmission line DTL3 includes the third horizontal connection line DHL3, the third vertical connection line DVL3, and the third additional vertical connection line DVL3’. However, the disclosure is not limited thereto.

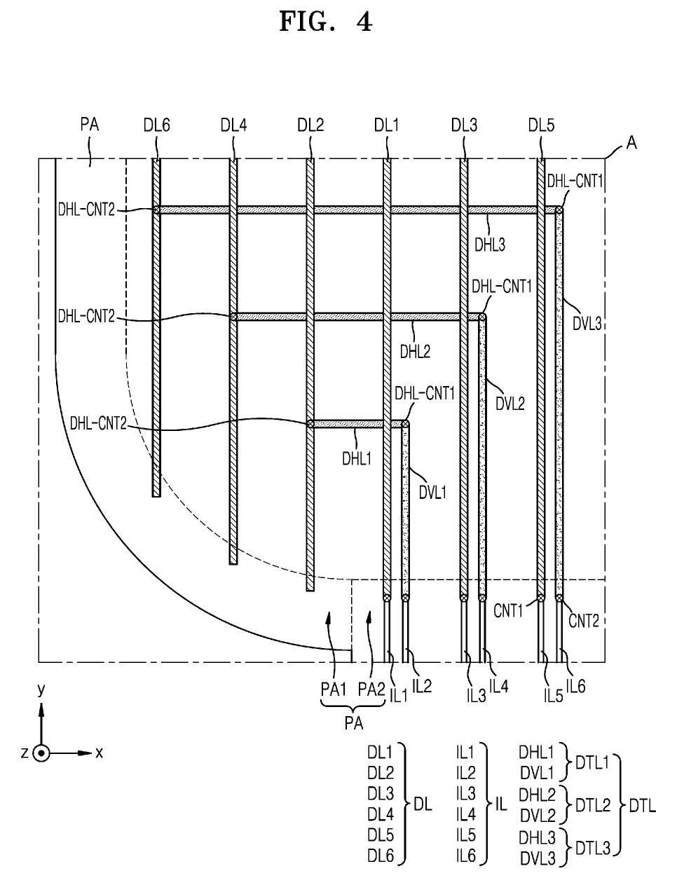

For example, as shown in FIG. 4, which is a schematic enlarged conceptual diagram of the region A of the display panel 10 according to an embodiment, the first data transmission line DTL1 may include the first horizontal connection line DHL1 and the first vertical connection line DVL1, the second data transmission line DTL2 may include the second horizontal connection line DHL2 and the second vertical connection line DVL2, and the third data transmission line DTL3 may include the third horizontal connection line DHL3 and the third vertical connection line DVL3. For example, each of the first horizontal connection line DHL1, the second horizontal connection line DHL2, and the third horizontal connection line DHL3 may be electrically connected to a corresponding one of the first vertical connection line DVL1, the second vertical connection line DVL2, and the third vertical connection line DVL3 through the first connection contact hole DHL-CNT1, and may be electrically connected to a corresponding one of the second data line DL2, the fourth data line DL4, and the sixth data line DL6 through the second connection contact hole DHL-CNT2.

FIG. 5 is an equivalent circuit diagram of the pixel circuit PC electrically connected to a light-emitting diode of the display panel 10, according to an embodiment.

The pixel circuit PC may include a plurality of transistors, e.g., first to eighth transistors T1 to T8, and a storage capacitor Cst, as shown in FIG. 5. One of the first to eighth transistors T1 to T8 may be a driving transistor, and the others may be switching transistors. Hereinafter, for descriptive convenience, the driving transistor is referred to as the first transistor T1, and the switching transistors are referred to as the second to eighth transistors T2 to T8.

The first to eighth transistors T1 to T8 and the storage capacitor Cst may be connected to signal lines, such as a first scan line GWL, a second scan line GCL, a third scan line GIL, a fourth scan line GBL, an emission control line EL, a data line DL, an initialization voltage line VIL, an electrode initialization voltage line VAL, a driving voltage line PL, and a bias voltage line VBL. At least one of the above lines, for example, the driving voltage line PL, may be shared by neighboring pixels.

The light-emitting diode LED may include a pixel electrode (e.g., an anode) and a common electrode (e.g., a cathode), and the pixel electrode may be connected to the first transistor T1 via the sixth transistor T6 to receive a driving current, and the common electrode may receive a common voltage ELVSS. The light-emitting diode LED may generate light of a luminance corresponding to the driving current.

Some of the first to eighth transistors T1 to T8 may be N-channel metal-oxide-semiconductor field-effect transistors (N-channel MOSFET) (NMOS transistors), and the others may be P-channel metal-oxide-semiconductor field-effect transistors (P-channel MOSFET) (PMOS transistors). For example, the third transistor T3 and the fourth transistor T4 among the first to eighth transistors T1 to T8 may be NMOS transistors, and the others may be PMOS transistors. In another example, the third transistor T3, the fourth transistor T4, and the seventh transistor T7 among the first to eighth transistors T1 to T8 may be NMOS transistors, and the others may be PMOS transistors. In another example, the first to eighth transistors T1 to T8 may be all NMOS transistors or all PMOS transistors. The first to eighth transistors T1 to T8 may be formed of amorphous silicon or polysilicon. If necessary, an NMOS transistor may include an oxide semiconductor. Hereinafter, for descriptive convenience, a case is described in which the third transistor T3 and the fourth transistor T4 are NMOS transistors including an oxide semiconductor, and the others are PMOS transistors.

The signal lines may include the first scan line GWL that transmits a first scan signal GW to the second transistor T2, the second scan line GCL that transmits a second scan signal GC to the third transistor T3, the third scan line GIL that transmits an initialization scan signal GI to the fourth transistor T4, the fourth scan line GBL that transmits a bias scan signal GB to the seventh transistor T7, the emission control line EL that transmits an emission control signal EM to the fifth transistor T5 and the sixth transistor T6, and the data line DL intersecting the first scan line GWL and that transmits a data signal DATA to the second transistor T2.

The driving voltage line PL may transmit a driving voltage ELVDD to the first transistor T1, the initialization voltage line VIL may transmit an initialization voltage Vint to initialize the first transistor T1 to a gate electrode of the first transistor T1, and the electrode initialization voltage line VAL may transmit an electrode initialization voltage Vaint to initialize the pixel electrode of the light-emitting diode LED to the pixel electrode.

The first transistor T1 may be a driving transistor. A gate electrode (hereinafter, a driving gate electrode or a first gate electrode) of the first transistor T1 may be connected to the storage capacitor Cst through a second node N2. One of a source region and a drain region of the first transistor T1 may be connected to the driving voltage line PL via the fifth transistor T5 through a first node N1, and the other of the source region and the drain region of the first transistor T1 may be electrically connected to the pixel electrode of the light-emitting diode LED via the sixth transistor T6 through a third node N3. The first transistor T1 may receive the data signal DATA according to a switching operation of the second transistor T2 and supply a driving current to the light-emitting diode LED.

The second transistor T2 may be a data writing transistor. A gate electrode (hereinafter, a second gate electrode) of the second transistor T2 may be connected to the first scan line GWL that transmits the first scan signal GW to the second transistor T2. One of a source region and a drain region of the second transistor T2 may be connected to the data line DL, and the other of the source region and the drain region of the second transistor T2 may be connected to the first transistor T1 through the first node N1 and connected to the driving voltage line PL via the fifth transistor T5. The second transistor T2 may transmit the data signal DATA from the data line DL to the first node N1, in response to a voltage applied to the first scan line GWL. For example, the second transistor T2 may be turned on in response to the first scan signal GW received through the first scan line GWL to perform a switching operation that transmits the data signal DATA received through the data line DL to the first transistor T1 through the first node N1.

The third transistor T3 may be a compensation transistor. A gate electrode (hereinafter, a third gate electrode) of the third transistor T3 may be connected to the second scan line GCL. One of a source region and a drain region of the third transistor T3 may be connected to the pixel electrode of the light-emitting diode LED via the sixth transistor T6 through the third node N3. The other of the source region and the drain region of the third transistor T3 may be connected to a first electrode of the storage capacitor Cst and the driving gate electrode of the first transistor T1 through the second node N2. The third transistor T3 may be turned on in response to the second scan signal GC received through the second scan line GCL to diode-connect the first transistor T1.

The fourth transistor T4 may be an initialization transistor, and a gate electrode (hereinafter, a fourth gate electrode) of the fourth transistor T4 may be connected to the third scan line GIL. One of a source region and a drain region of the fourth transistor T4 may be connected to the initialization voltage line VIL. The other of the source region and the drain region of the fourth transistor T4 may be connected to the first electrode of the storage capacitor Cst and the driving gate electrode of the first transistor T1 through the second node N2. The fourth transistor T4 may apply the initialization voltage Vint from the initialization voltage line VIL to the second node N2, in response to a voltage applied to the third scan line GIL. The fourth transistor T4 may be turned on in response to the initialization scan signal GI received through the third scan line GIL to perform an initialization operation of initializing a voltage of the driving gate electrode of the first transistor T1 by transmitting the initialization voltage Vint to the driving gate electrode of the first transistor T1.

The fifth transistor T5 may be an operation control transistor. A gate electrode (hereinafter, a fifth gate electrode) of the fifth transistor T5 may be connected to the emission control line EL. One of a source region and a drain region of the fifth transistor T5 may be connected to the driving voltage line PL, and the other of the source region and the drain region of the fifth transistor T5 may be connected to the first transistor T1 and the second transistor T2 through the first node N1.

The sixth transistor T6 may be an emission control transistor. A gate electrode (hereinafter, a sixth gate electrode) of the sixth transistor T6 may be connected to the emission control line EL. One of a source region and a drain region of the sixth transistor T6 may be connected to the first transistor T1 and the third transistor T3 through the third node N3, and the other of the source region and the drain region of the sixth transistor T6 may be electrically connected to the pixel electrode of the light-emitting diode LED.

The fifth transistor T5 and the sixth transistor T6 may be simultaneously turned on in response to the emission control signal EM received through the emission control line EL to transmit an electrical signal from the driving voltage line PL to the light-emitting diode LED, thereby allowing a driving current to flow through the light-emitting diode LED.

The seventh transistor T7 may be an electrode initialization transistor. A gate electrode (hereinafter, a seventh gate electrode) of the seventh transistor T7 may be connected to the fourth scan line GBL. One of a source region and a drain region of the seventh transistor T7 may be connected to the pixel electrode of the light-emitting diode LED, and the other of the source region and the drain region of the seventh transistor T7 may be connected to the electrode initialization voltage line VAL to receive the electrode initialization voltage Vaint. The seventh transistor T7 may be turned on in response to the bias scan signal GB received through the fourth scan line GBL to initialize the pixel electrode of the light-emitting diode LED.

The eighth transistor T8 may be a bias transistor, and may be connected between the first node N1 and the bias voltage line VBL. A gate electrode (hereinafter, an eighth gate electrode) of the eighth transistor T8 may be connected to the fourth scan line GBL. One of a source region and a drain region of the eighth transistor T8 may be connected to the first node N1, and the other of the source region and the drain region of the eighth transistor T8 may be connected to the bias voltage line VBL. The eighth transistor T8 may be turned on in response to the bias scan signal GB received through the fourth scan line GBL to apply a bias voltage VOBS to the first node N1, to preset a voltage suitable for a subsequent operation of the first transistor T1 to the first node N1. The fourth scan line GBL may be referred to as a bias gate line.

The storage capacitor Cst may include a first electrode and a second electrode. The first electrode of the storage capacitor Cst may be connected to the driving gate electrode of the first transistor T1 through the second node N2, and the second electrode of the storage capacitor Cst may be connected to the driving voltage line PL. The storage capacitor Cst may store a charge corresponding to a difference between the voltage of the driving gate electrode of the first transistor T1 and the driving voltage ELVDD.

A detailed operation of each pixel according to an embodiment is as follows.

During an initialization period, when the initialization scan signal GI is supplied through the third scan line GIL, the fourth transistor T4 may be turned on in response to the initialization scan signal GI, and the first transistor T1 may be initialized by the initialization voltage Vint supplied from the initialization voltage line VIL. For example, when the bias scan signal GB is supplied through the fourth scan line GBL, the seventh transistor T7 may be turned on in response to the bias scan signal GB, and the pixel electrode of the light-emitting diode LED may be initialized by the electrode initialization voltage Vaint supplied from the electrode initialization voltage line VAL. For example, the eighth transistor T8 may also be turned on in response to the bias scan signal GB to apply the bias voltage VOBS to the first node N1, to preset a voltage suitable for a subsequent operation of the first transistor T1 to the first node N1.

During a data programming period, when the first scan signal GW and the second scan signal GC are supplied through the first scan line GWL and the second scan line GCL, respectively, the second transistor T2 and the third transistor T3 may be turned on in response to the first scan signal GW and the second scan signal GC, respectively. For example, the first transistor T1 may be diode-connected by the third transistor T3 that has been turned on, thereby forward-biasing the first transistor T1. For example, a compensation voltage (DATA+Vth, where Vth is a (-) negative value), which is obtained by subtracting a threshold voltage (Vth) of the first transistor T1 from the data signal DATA supplied from the data line DL, may be applied to the driving gate electrode of the first transistor T1. The driving voltage ELVDD and the compensation voltage (DATA+Vth) may be applied to two end portions of the storage capacitor Cst, respectively, and a charge corresponding to a difference between the voltages of the two ends may be stored in the storage capacitor Cst.

During an emission period, the fifth transistor T5 and the sixth transistor T6 may be turned on by the emission control signal EM supplied from the emission control line EL. A driving current may be generated according to a difference between the voltage of the driving gate electrode of the first transistor T1 and the driving voltage ELVDD, and the driving current may be supplied to the light-emitting diode LED through the sixth transistor T6.

As described above, some of the first to eighth transistors T1 to T8 may include an oxide semiconductor. For example, the third transistor T3 and the fourth transistor T4 may include an oxide semiconductor.

Because polysilicon has high reliability, when the first transistor T1 that directly affects the brightness of the display panel 10 includes a semiconductor layer including polysilicon with high reliability, a high-resolution display panel may be implemented. Meanwhile, because an oxide semiconductor has high carrier mobility and low leakage current, a voltage drop may be small although a pixel driving time increases. For example, in the case of an oxide semiconductor, a color change of an image due to a voltage drop may be reduced or minimized even during a low-frequency driving period, and thus, low-frequency driving operation may be performed. Accordingly, when the third transistor T3 and the fourth transistor T4 include an oxide semiconductor, leakage current may be prevented from occurring, and the power consumption of a display panel 10 may be reduced or minimized.

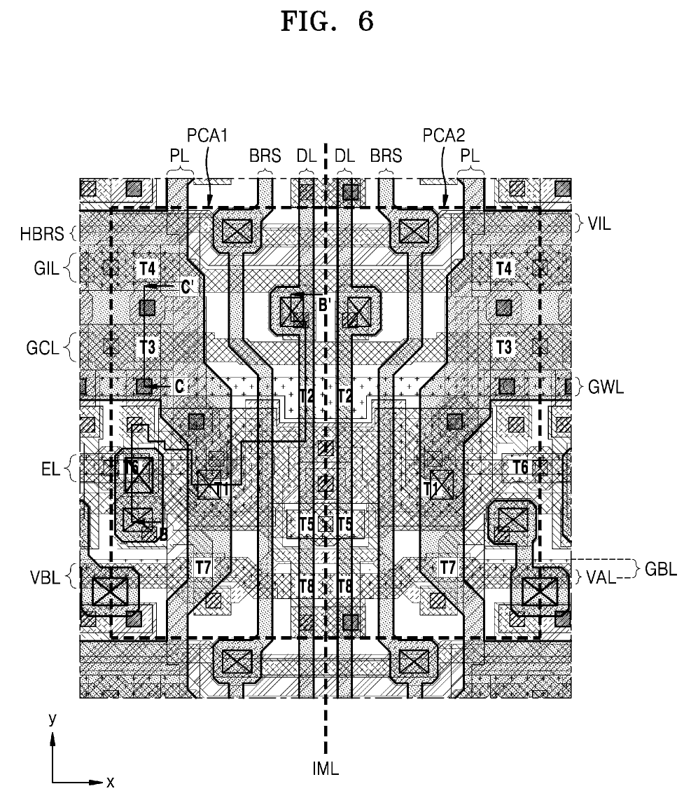

FIG. 6 is a schematic plan view showing positions of transistors and capacitors corresponding to pixels included in the display panel 10, according to an embodiment. For descriptive convenience, in FIG. 6, only transistors and capacitors are shown, but light-emitting diodes are omitted. However, light-emitting diodes electrically connected to the transistors and the capacitors may be arranged on the transistors and the capacitors.

The display panel 10 (see FIG. 2) may include pixel circuit areas arranged in the first direction (e.g., x-axis direction) and the second direction (e.g., y-axis direction). FIG. 6 shows two pixel circuits arranged in two adjacent pixel circuit areas (e.g., a first pixel circuit area PCA1 and a second pixel circuit area PCA2) among a plurality of pixel circuit areas. In each of the first pixel circuit area PCA1 and the second pixel circuit area PCA2 shown in FIG. 6, the first to eighth transistors T1 to T8 and the storage capacitor Cst of the corresponding pixel circuit may be arranged.

Adjacent pixel circuits, for example, the first to eighth transistors T1 to T8 and the storage capacitors Cst that are respectively arranged in the first pixel circuit area PCA1 and the second pixel circuit area PCA2 as shown in FIG. 6, may be substantially symmetrical with respect to an imaginary boundary line IML. For example, transistors and a storage capacitor arranged in another pixel circuit area on the left side of the first pixel circuit area PCA1 may be substantially symmetrical to the first to eighth transistors T1 to T8 and the storage capacitor Cst arranged in the first pixel circuit area PCA1, with respect to an imaginary boundary line between the first pixel circuit area PCA1 and the other pixel circuit area. Transistors and a storage capacitor arranged in another pixel circuit area on the right side of the second pixel circuit area PCA2 may be substantially symmetrical to the first to eighth transistors T1 to T8 and the storage capacitor Cst arranged in the second pixel circuit area PCA2, with respect to an imaginary boundary line between the second pixel circuit area PCA2 and the other pixel circuit area.

The data line DL and the driving voltage line PL passing through the first pixel circuit area PCA1 may be symmetrical to the data line DL and the driving voltage line PL passing through the second pixel circuit area PCA2, with respect to the imaginary boundary line IML.

The data line DL and the driving voltage line PL may each extend in the second direction (e.g., y-axis direction). The data line DL and the driving voltage line PL may be shared by adjacent pixel circuits arranged in the same column direction (e.g., the second direction).

The first scan line GWL, the second scan line GCL, the third scan line GIL, the fourth scan line GBL, the emission control line EL, the initialization voltage line VIL, the electrode initialization voltage line VAL, and the bias voltage line VBL, each extending in the first direction (e.g., x-axis direction), may be shared by adjacent pixel circuits arranged in the same row direction (e.g., the first direction).

The display panel 10 may include a vertical wiring BRS and a horizontal wiring HBRS between the data line DL and the driving voltage line PL that extend in the second direction (e.g., y-axis direction). In some embodiments, the vertical wiring BRS and the horizontal wiring HBRS may correspond to the vertical connection line and the horizontal connection line described above with reference to FIG. 3 and/or FIG. 4, respectively.

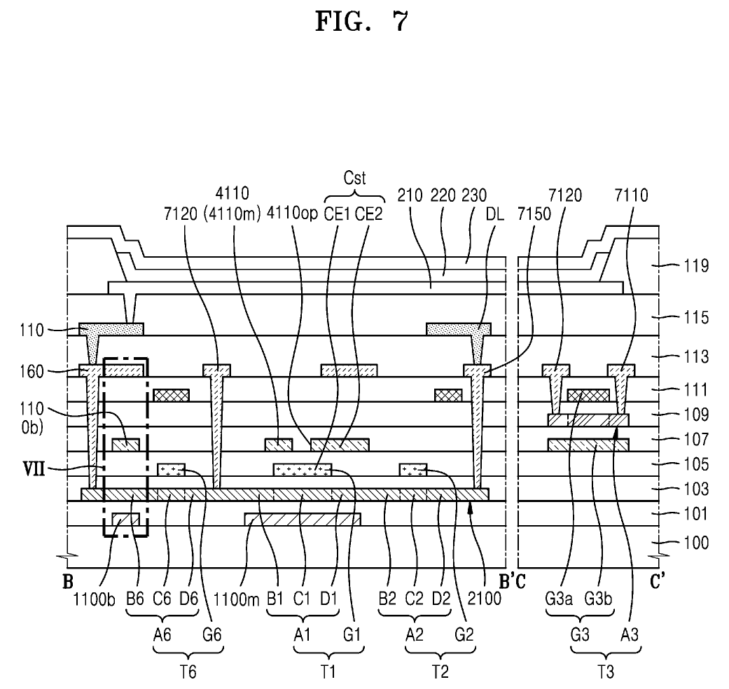

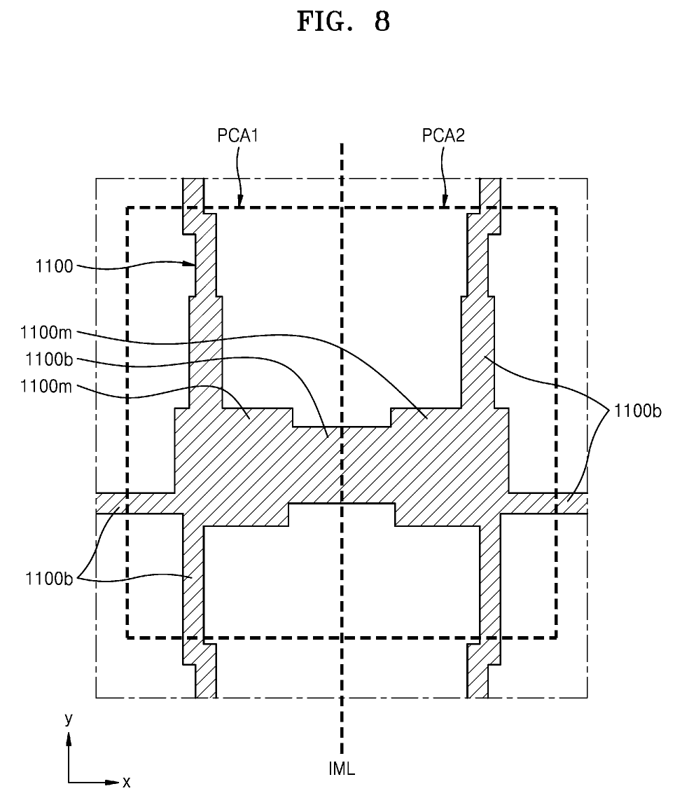

FIG. 7 is a cross-sectional view of a pixel circuit of the display panel 10 and a light-emitting diode electrically connected to the pixel circuit, according to an embodiment, and the transistors and the storage capacitor shown in FIG. 7 correspond to cross sections taken along lines B-B’ and C-C’ of FIG. 6. FIGS. 8 to 15 are schematic plan views showing components, such as transistors and capacitors, of the display panel 10 shown in FIG. 6 for each layer.

Referring to FIGS. 7 and 8, a lower conductive layer 1100 may be arranged on a substrate 100, and a buffer layer 101 may be arranged on the lower conductive layer 1100.

The substrate 100 may include glass, ceramic, metal, or polymer resin. The substrate 100 may include, for example, polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layer structure including at least two layers including the above polymer resin and an inorganic layer between at least the two layers. In another example, the substrate 100 may have a structure in which a layer including the above polymer resin and an inorganic layer are alternately stacked. The inorganic layer may include, for example, silicon oxide, silicon nitride, or silicon oxynitride.

The lower conductive layer 1100 may be a metal layer including a metal element. The lower conductive layer 1100 may include a metal such as molybdenum, titanium, or aluminum. The lower conductive layer 1100 may be, for example, a single layer including molybdenum, a double layer including a molybdenum layer and a titanium layer, or a triple layer including a titanium layer, an aluminum layer, and a titanium layer.

As shown in FIG. 8, the lower conductive layer 1100 may include a main portion 1100m arranged in each of the first and second pixel circuit areas PCA1 and PCA2, and branch portions 1100b extending from the main portion 1100m in the first direction (e.g., x-axis direction) and the second direction (e.g., y-axis direction), respectively.

The main portions 1100m and the branch portions 1100b, which are respectively arranged in the first and second pixel circuit areas PCA1 and PCA2, may be substantially symmetrical with respect to the imaginary boundary line IML. The branch portions 1100b may be connected to the main portion 1100m as a single body. The main portions 1100m arranged in adjacent pixel circuit areas in a row direction (e.g., the first direction) and a column direction (e.g., the second direction) may be connected to each other by the branch portion 1100b.

The lower conductive layer 1100 may have a constant voltage level. In an embodiment, the lower conductive layer 1100 may have a voltage level of the driving voltage ELVDD (see FIG. 5).

The buffer layer 101 may prevent metal atoms or impurities from diffusing from the substrate 100 to a first semiconductor pattern 2100 positioned on the substrate 100. For example, the buffer layer 101 may control the rate of heat transfer during a crystallization process for forming the first semiconductor pattern 2100, thereby enabling uniform crystallization of the first semiconductor pattern 2100.

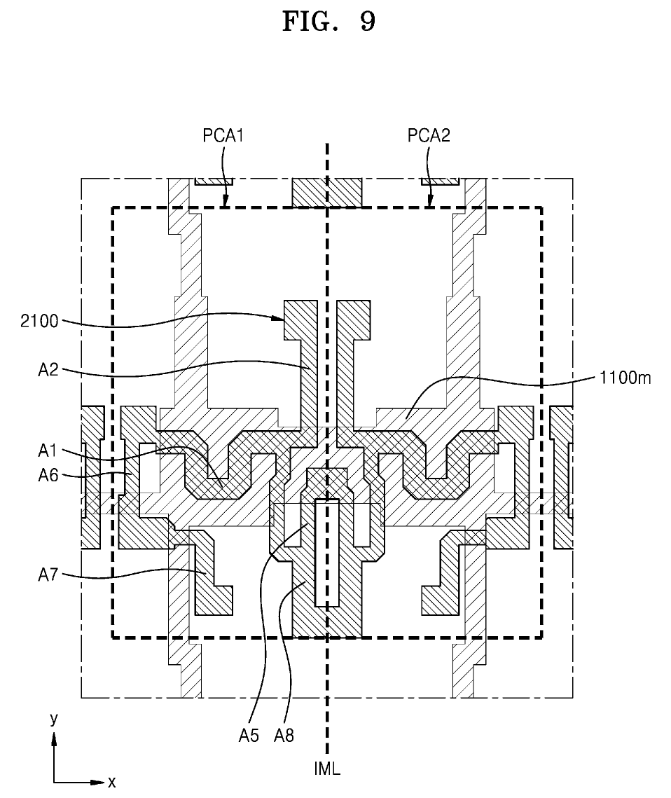

Referring to FIGS. 7 and 9, the first semiconductor pattern 2100 may be arranged on the buffer layer 101, and may include a silicon semiconductor. For example, the first semiconductor pattern 2100 may include amorphous silicon or polysilicon. For example, the first semiconductor pattern 2100 may include polysilicon that is crystallized at a low temperature. A portion of the first semiconductor pattern 2100 may be doped with ions.

The first semiconductor pattern 2100 may be bent to form various shapes. The first semiconductor pattern 2100 may include semiconductor layers of some of the transistors described above with reference to FIG. 5, for example, a first semiconductor layer A1 of the first transistor T1, a second semiconductor layer A2 of the second transistor T2, a fifth semiconductor layer A5 of the fifth transistor T5, a sixth semiconductor layer A6 of the sixth transistor T6, a seventh semiconductor layer A7 of the seventh transistor T7, and an eighth semiconductor layer A8 of the eighth transistor T8.

The first semiconductor layers A1, the second semiconductor layers A2, the fifth semiconductor layers A5, the sixth semiconductor layers A6, the seventh semiconductor layers A7, and the eighth semiconductor layers A8, which are respectively arranged in the first and second pixel circuit areas PCA1 and PCA2, may be substantially symmetrical with respect to the imaginary boundary line IML. The first semiconductor layer A1, the second semiconductor layer A2, the fifth semiconductor layer A5, the sixth semiconductor layer A6, the seventh semiconductor layer A7, and the eighth semiconductor layer A8 of each pixel circuit area may be connected to each other as a single body (or single/integrated semiconductor pattern).

Each of the first semiconductor layer A1, the second semiconductor layer A2, the fifth semiconductor layer A5, the sixth semiconductor layer A6, the seventh semiconductor layer A7, and the eighth semiconductor layer A8 may include a channel region, and first and second regions respectively arranged on two sides (e.g., opposite sides) of the channel region. In this regard, FIG. 7 shows that the first, second, and sixth semiconductor layers A1, A2, and A6 respectively include channel regions C1, C2, and C6, and first regions B1, B2, and B6 and second regions D1, D2, and D6 that are respectively arranged on two sides (e.g., opposite sides) of the channel regions C1, C2, and C6. The first regions B1, B2, and B6 and the second regions D1, D2, and D6 may be doped regions doped with ions.

One of the first and second regions B1 and D1 of the first semiconductor layer A1 may be a source region, and the other may be a drain region. In an embodiment, the first region B1 may be a drain region, and the second region D1 may be a source region.

A portion of the first semiconductor pattern 2100, for example, the first semiconductor layer A1, may overlap the main portion 1100m of the lower conductive layer 1100. The main portion 1100m may protect the first semiconductor layer A1. The channel region C1 of the first semiconductor layer A1 may overlap (e.g., entirely overlap) the main portion 1100m of the lower conductive layer 1100. The channel region C1 of the first semiconductor layer A1 may have a substantially inverted omega shape or a horseshoe shape in a plan view.

A first insulating layer 103 may be arranged on the first semiconductor pattern 2100. The first insulating layer 103 may include an inorganic insulating layer including silicon oxide, silicon nitride, silicon oxynitride, or aluminum oxide.

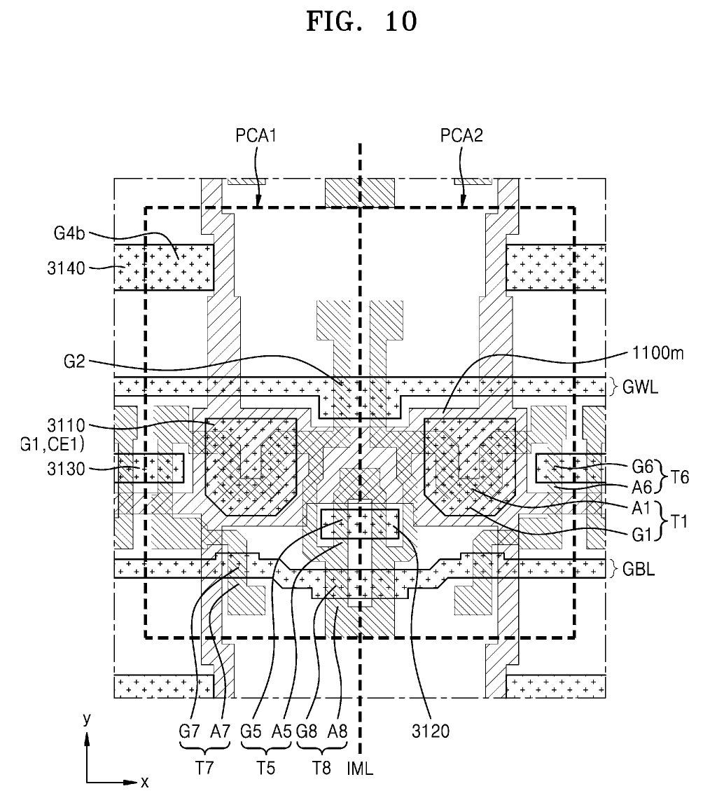

Referring to FIGS. 7 and 10, conductive layers and scan lines, which include gate electrodes, may be arranged on the first insulating layer 103. For example, a first conductive layer 3110 including a first gate electrode G1, a first scan line GWL including a second gate electrode G2, a second conductive layer 3120 including a fifth gate electrode G5, a third conductive layer 3130 including a sixth gate electrode G6, a fourth conductive layer 3140 including a fourth lower gate electrode G4b, and a fourth scan line GBL including a seventh gate electrode G7 and an eighth gate electrode G8 may be arranged on the first insulating layer 103.

The first conductive layers 3110, the second conductive layers 3120, the third conductive layers 3130, and the fourth conductive layers 3140, which are respectively arranged in the first and second pixel circuit areas PCA1 and PCA2, may be substantially symmetrical with respect to the imaginary boundary line IML. The second conductive layer 3120 may be shared by pixel circuits to be arranged in the first and second pixel circuit areas PCA1 and PCA2. The first scan line GWL and the fourth scan line GBL may extend substantially in the first direction (e.g., x-axis direction).

The first conductive layer 3110 may have an isolated shape, and may overlap the channel region of the first semiconductor layer A1. The first conductive layer 3110 may overlap the main portion 1100m of the lower conductive layer 1100 arranged below the first semiconductor layer A1. The first conductive layer 3110 may include the first gate electrode G1 of the first transistor T1, and may function as a first electrode CE1 (see FIG. 7), which is a lower electrode of the storage capacitor Cst.

The second conductive layer 3120 may include the fifth gate electrode G5 overlapping the channel region of the fifth semiconductor layer A5 of the fifth transistor T5.

The third conductive layer 3130 may include the sixth gate electrode G6 overlapping the channel region of the sixth semiconductor layer A6 of the sixth transistor T6.

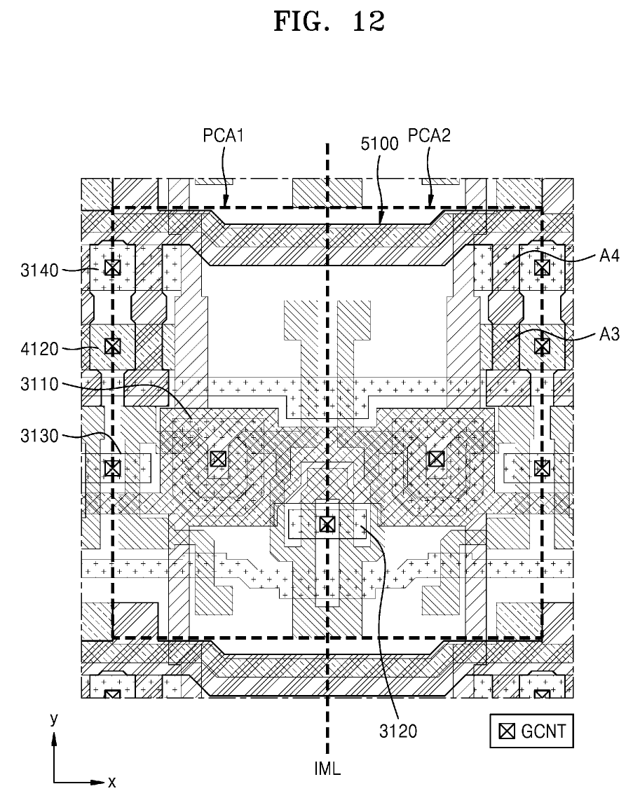

The fourth conductive layer 3140 may include the fourth lower gate electrode G4b that is a portion of the fourth gate electrode of the fourth transistor T4, is arranged below a fourth semiconductor layer A4 of the fourth transistor T4 to be described below with reference to FIG. 12, and overlaps a channel region of the fourth semiconductor layer A4.

A portion of the first scan line GWL, which overlaps the second semiconductor layer A2, may correspond to the second gate electrode G2 of the second transistor T2. A portion of the fourth scan line GBL, which overlaps the seventh semiconductor layer A7, may correspond to the seventh gate electrode G7 of the seventh transistor T7, and a portion of the fourth scan line GBL, which overlaps the eighth semiconductor layer A8, may correspond to the eighth gate electrode G8 of the eighth transistor T8.

The first conductive layer 3110, the first scan line GWL, the second conductive layer 3120, the third conductive layer 3130, the fourth conductive layer 3140, and the fourth scan line GBL may include a metal, an alloy, a conductive metal oxide, etc. For example, the first conductive layer 3110, the first scan line GWL, the second conductive layer 3120, the third conductive layer 3130, the fourth conductive layer 3140, and the fourth scan line GBL may include silver (Ag), an Ag-containing alloy, molybdenum (Mo), a Mo-containing alloy, aluminum (Al), an Al-containing alloy, aluminum nitride (AlNₓ), tungsten (W), tungsten nitride (WNₓ), copper (Cu), nickel (Ni), chromium (Cr), chromium nitride (CrNₓ), titanium (Ti), tantalum (Ta), platinum (Pt), or scandium (Sc), and may be formed in a multi-layer structure or a single-layer structure including the above-described material.

A second insulating layer 105 may be arranged on the first conductive layer 3110, the first scan line GWL, the second conductive layer 3120, the third conductive layer 3130, the fourth conductive layer 3140, and the fourth scan line GBL. The second insulating layer 105 may include an inorganic insulating layer including silicon oxide, silicon nitride, silicon oxynitride, or aluminum oxide.

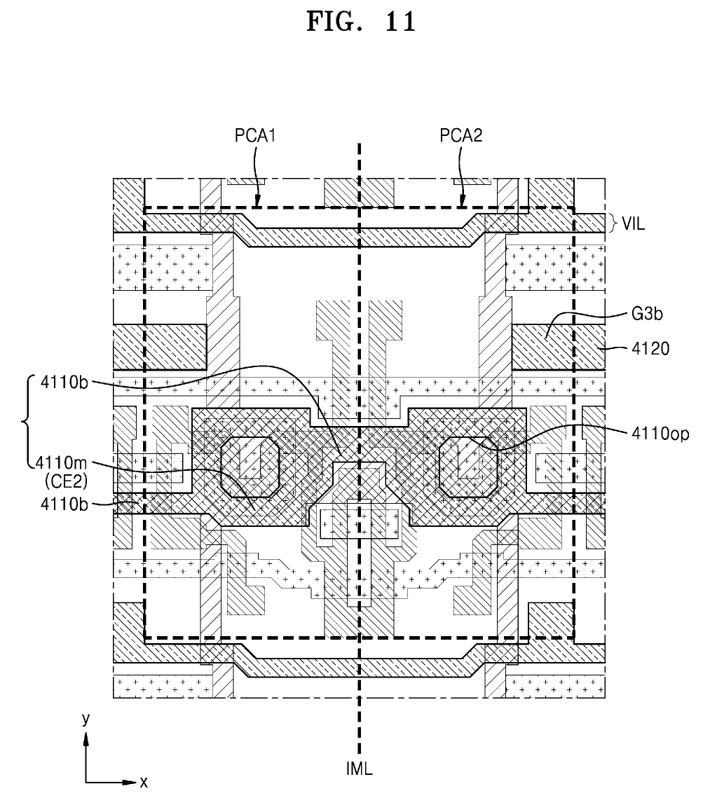

Referring to FIGS. 7 and 11, an electrode voltage line 4110, an initialization voltage line VIL, and a fifth conductive layer 4120 may be arranged on the second insulating layer 105.

The electrode voltage line 4110 may include a main portion 4110m overlapping the first conductive layer 3110 (see FIG. 10) and a branch portion 4110b extending from the main portion 4110m in the first direction (e.g., x-axis direction). The main portion 4110m may include an opening 4110op overlapping a portion of the first conductive layer 3110 (see FIG. 10). The electrode voltage line 4110 may be electrically connected to the driving voltage line PL (see FIG. 6), and may include a second electrode CE2, which is an upper electrode of the storage capacitor Cst.

The main portions 4110m, which are respectively arranged in the first and second pixel circuit areas PCA1 and PCA2, may be substantially symmetrical with respect to the imaginary boundary line IML. The branch portion 4110b may connect the main portions 4110m to each other, and the electrode voltage line 4110 may extend substantially in the first direction (e.g., x-axis direction) by a connection structure of the main portion 4110m and the branch portion 4110b. The branch portion 4110b of the electrode voltage line 4110 may overlap the branch portion 1100b (see FIG. 8) of the lower conductive layer 1100. The electrode voltage line 4110 may be shared by pixel circuits arranged in the same row direction (e.g., in the first direction).

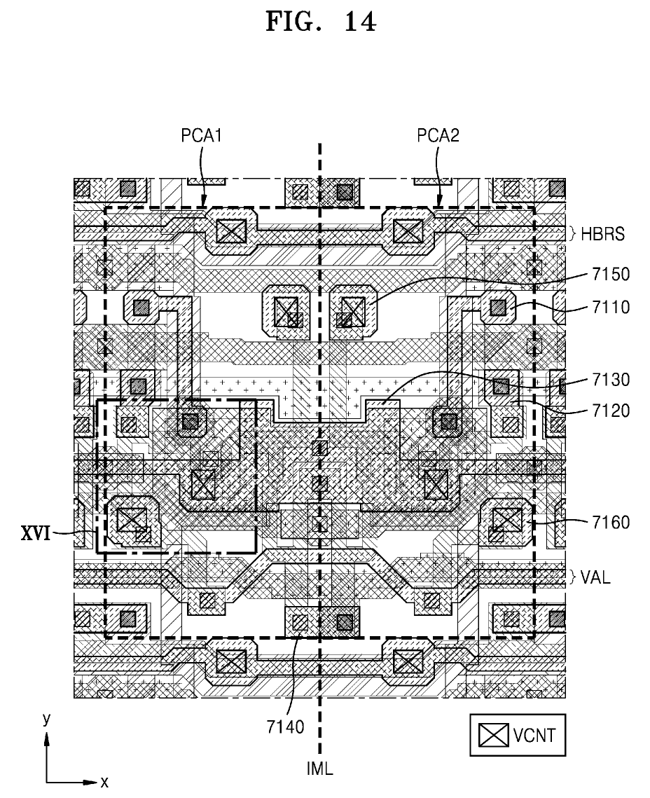

The electrode voltage line 4110 may be electrically connected to the driving voltage line PL (see FIG. 6) through a third connection electrode 7130 to be described below with reference to FIG. 14, and may have a constant voltage level, which is substantially equal to the driving voltage ELVDD. When static electricity is introduced from the outside, the static electricity may spread (or dissipate) through the electrode voltage line 4110 extending in the first direction (e.g., x-axis direction), thereby preventing, reducing, or minimizing the influence on a pixel circuit.

The initialization voltage line VIL may extend substantially in the first direction (e.g., x-axis direction). The initialization voltage line VIL may be shared by pixel circuits to be arranged in the first and second pixel circuit areas PCA1 and PCA2.

The fifth conductive layer 4120 may be positioned between the electrode voltage line 4110 and the initialization voltage line VIL in a plan view. The fifth conductive layers 4120, which are respectively arranged in the first and second pixel circuit areas PCA1 and PCA2, may be substantially symmetrical with respect to the imaginary boundary line IML. The fifth conductive layer 4120 may include a third lower gate electrode G3b, which is a portion of the third gate electrode G3 of the third transistor T3, is arranged below a third semiconductor layer A3 of the third transistor T3, and overlaps a channel region of the third semiconductor layer A3.

The electrode voltage line 4110, the initialization voltage line VIL, and the fifth conductive layer 4120 may include a metal, an alloy, a conductive metal oxide, etc. For example, the electrode voltage line 4110, the initialization voltage line VIL, and the fifth conductive layer 4120 may include Ag, an Ag-containing alloy, Mo, an Mo-containing alloy, Al, an Al-containing alloy, AlNₓ, W, WNₓ, Cu, Ni, Cr, CrNₓ, Ti, Ta, Pt, or Sc, and may be formed in a multi-layer structure or a single-layer structure including the above-described material.

A third insulating layer 107 may be arranged on the electrode voltage line 4110, the initialization voltage line VIL, and the fifth conductive layer 4120. The third insulating layer 107 may include an inorganic insulating layer including silicon oxide, silicon nitride, silicon oxynitride, or aluminum oxide.

Referring to FIGS. 7 and 12, a second semiconductor pattern 5100 may be arranged on the third insulating layer 107. The second semiconductor pattern 5100 may include a portion extending in the first direction (e.g., x-axis direction) and a portion extending in the second direction (e.g., y-axis direction) and overlapping the fifth conductive layer 4120 and the fourth conductive layer 3140 therebelow.

The second semiconductor pattern 5100 may include an oxide semiconductor. The second semiconductor pattern 5100 may be arranged on a different layer from the first semiconductor pattern 2100, and may not overlap the first semiconductor pattern 2100 when viewed in a direction perpendicular to the substrate 100 (e.g., z-axis direction) or in a plan view. A third transistor T3 and a fourth transistor T4 may be formed along the second semiconductor pattern 5100. As shown in FIG. 12, the second semiconductor pattern 5100 may include third and fourth semiconductor layers A3 and A4 of the third and fourth transistors T3 and T4. The third semiconductor layer A3 may include a channel region overlapping the fifth conductive layer 4120, and a source region and a drain region that are respectively arranged on two sides (e.g., opposite sides) of the channel region. The fourth semiconductor layer A4 may include a channel region overlapping the fourth conductive layer 3140, and a source region and a drain region that are respectively arranged on two sides (e.g., opposite sides) of the channel region.

A fourth insulating layer 109 may be arranged on the second semiconductor pattern 5100. The fourth insulating layer 109 may include an inorganic insulating layer including silicon oxide, silicon nitride, silicon oxynitride, or aluminum oxide.

Contact holes GCNT may be formed in the first and second pixel circuit areas PCA1 and PCA2. The contact holes GCNT may overlap conductive layers corresponding to gate electrodes of transistors. For example, the contact holes GCNT may overlap the first conductive layer 3110, the second conductive layer 3120, the third conductive layer 3130, the fourth conductive layer 3140, and the fifth conductive layer 4120, respectively. The contact holes GCNT, which are respectively arranged the first and second pixel circuit areas PCA1 and PCA2, may be substantially symmetrical with respect to the imaginary boundary line IML.

The contact holes GCNT overlapping the first conductive layer 3110, the second conductive layer 3120, the third conductive layer 3130, and the fourth conductive layer 3140 may penetrate (or pass through) the fourth insulating layer 109, the third insulating layer 107, and the second insulating layer 105. The contact hole GCNT overlapping the fifth conductive layer 4120 may penetrate (or pass through) the fourth insulating layer 109 and the third insulating layer 107.

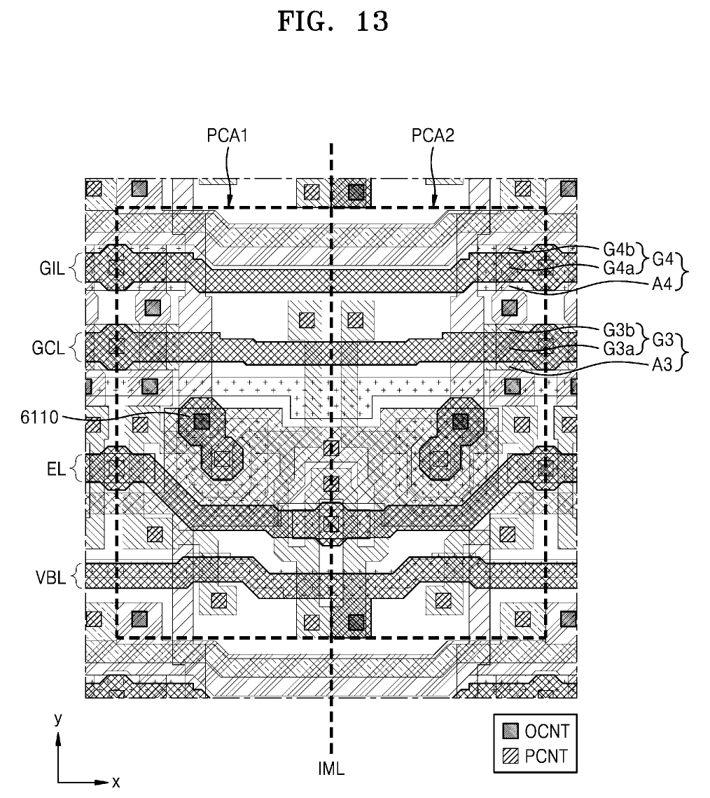

Referring to FIGS. 7 and 13, a first connection electrode 6110, a second scan line GCL, a third scan line GIL, an emission control line EL, and a bias voltage line VBL may be arranged on the fourth insulating layer 109.

The first connection electrode 6110 may have an isolated shape, and may be electrically connected to the first conductive layer 3110 through the contact hole GCNT described with reference to FIG. 12. Because the electrode voltage line 4110 (see FIG. 11) includes the opening 4110op, the first connection electrode 6110 may be electrically connected to (e.g., in direct contact with) the first conductive layer 3110 through the contact hole GCNT formed in the opening 4110op.

The second scan line GCL, the third scan line GIL, the emission control line EL, and the bias voltage line VBL may extend substantially in the first direction (e.g., x-axis direction).

The second scan line GCL may be electrically connected to the fifth conductive layer 4120 through the contact hole GCNT described with reference to FIG. 12. A portion of the second scan line GCL, which overlaps the third semiconductor layer A3 of the third transistor T3, may correspond to a third gate electrode G3. The third gate electrode G3 may include a third upper gate electrode G3a above the channel region of the third semiconductor layer A3 and a third lower gate electrode G3b below the channel region, and a portion of the second scan line GCL may correspond to the third upper gate electrode G3a.

The third scan line GIL may be electrically connected to the fifth conductive layer 4120 through the contact hole GCNT described with reference to FIG. 12. A portion of the third scan line GIL, which overlaps the channel region of the fourth semiconductor layer A4 of the fourth transistor T4, may correspond to a fourth gate electrode G4. The fourth gate electrode G4 may include a fourth upper gate electrode G4a above the channel region of the fourth semiconductor layer A4 and a fourth lower gate electrode G4b below the channel region, and a portion of the third scan line GIL may correspond to the fourth upper gate electrode G4a.

The emission control line EL may be electrically connected to the second conductive layer 3120 and the third conductive layer 3130 through the contact holes GCNT described with reference to FIG. 12, respectively.

The first connection electrode 6110, the second scan line GCL, the third scan line GIL, the emission control line EL, and the bias voltage line VBL may be formed of a metal, an alloy, a conductive metal oxide, etc. For example, the first connection electrode 6110, the second scan line GCL, the third scan line GIL, the emission control line EL, and the bias voltage line VBL may include Ag, an Ag-containing alloy, Mo, a Mo-containing alloy, Al, an Al-containing alloy, AlNₓ, W, WNₓ, Cu, Ni, Cr, CrNₓ, Ti, Ta, Pt, or Sc, and may be formed in a multi-layer structure or a single-layer structure including the above-described material.

A fifth insulating layer 111 may be arranged on the first connection electrode 6110, the second scan line GCL, the third scan line GIL, the emission control line EL, and the bias voltage line VBL. The fifth insulating layer 111 may include an inorganic insulating layer including silicon oxide, silicon nitride, silicon oxynitride, or aluminum oxide.

Contact holes OCNT and PCNT may be formed in the first and second pixel circuit areas PCA1 and PCA2. The contact holes OCNT and PCNT, which are respectively arranged the first and second pixel circuit areas PCA1 and PCA2, may be substantially symmetrical with respect to the imaginary boundary line IML.

Some contact holes PCNT may overlap the first semiconductor pattern 2100 (see FIG. 9) or the electrode voltage line 4110. Portions of the first semiconductor pattern 2100 (see FIG. 9) and a portion of the electrode voltage line 4110 may be exposed through the contact holes PCNT.

Other contact holes OCNT may overlap the third and fourth semiconductor layers A3 and A4 of the second semiconductor pattern 5100 (see FIG. 12), the first connection electrode 6110, and the bias voltage line VBL. Portions of the third and fourth semiconductor layers A3 and A4, a portion of the first connection electrode 6110, and a portion of the bias voltage line VBL may be exposed through the contact holes OCNT.

Referring to FIGS. 7 and 14, a bridge electrode 7110, a second connection electrode 7120, a third connection electrode 7130, a fourth connection electrode 7140, a fifth connection electrode 7150, a sixth connection electrode 7160, an electrode initialization voltage line VAL, and a horizontal wiring HBRS may be arranged on the fifth insulating layer 111.

The bridge electrode 7110, the second connection electrode 7120, the third connection electrode 7130, the fourth connection electrode 7140, the fifth connection electrode 7150, the sixth connection electrode 7160, the electrode initialization voltage line VAL, and the horizontal wiring HBRS may include a metal, an alloy, a conductive metal oxide, etc. For example, the bridge electrode 7110, the second connection electrode 7120, the third connection electrode 7130, the fourth connection electrode 7140, the fifth connection electrode 7150, the sixth connection electrode 7160, the electrode initialization voltage line VAL, and the horizontal wiring HBRS may include Ag, an Ag-containing alloy, Mo, a Mo-containing alloy, Al, an Al-containing alloy, AlNₓ, W, WNₓ, Cu, Ni, Cr, CrNₓ, Ti, Ta, Pt, or Sc, and may have a multi-layer structure or a single-layer structure including the above-described material.

The bridge electrode 7110 may electrically connect the first gate electrode G1 of the first transistor T1 and the third semiconductor layer A3 of the third transistor T3 to each other. The bridge electrode 7110 may electrically connect the first conductive layer 3110 and the second semiconductor pattern 5100 including the third semiconductor layer A3 to each other. For example, a portion of the bridge electrode 7110 may be electrically connected to (or be in contact with) the first connection electrode 6110 through the contact hole OCNT described with reference to FIG. 13, and another portion of the bridge electrode 7110 may be electrically connected to (or, be in contact with) the third semiconductor layer A3 through the contact hole OCNT.

When viewed in a direction perpendicular to an upper surface of the substrate 100 (or in a plan view), the bridge electrode 7110 may overlap the branch portion 1100b of the lower conductive layer 1100 described with reference to FIG. 8, which extends from the main portion 1100m of the lower conductive layer 1100 in the second direction (e.g., y-axis direction). Because the bridge electrode 7110 overlaps the lower conductive layer 1100 having a constant voltage level, the occurrence of unnecessary parasitic capacitance may be prevented, reduced, or minimized.

The second connection electrode 7120 may function as the third node N3 described with reference to FIG. 5, and may electrically connect the third semiconductor layer A3, the first semiconductor layer A1, and the sixth semiconductor layer A6 to each other. The second connection electrode 7120 may be electrically connected to (or, be in contact with) the second semiconductor pattern 5100 (see FIG. 12) including the third semiconductor layer A3 through the contact hole OCNT, and may be electrically connected to (or, be in contact with) the first semiconductor pattern 2100 (see FIG. 9) including the first semiconductor layer A1 and the sixth semiconductor layer A6 through the contact hole PCNT.

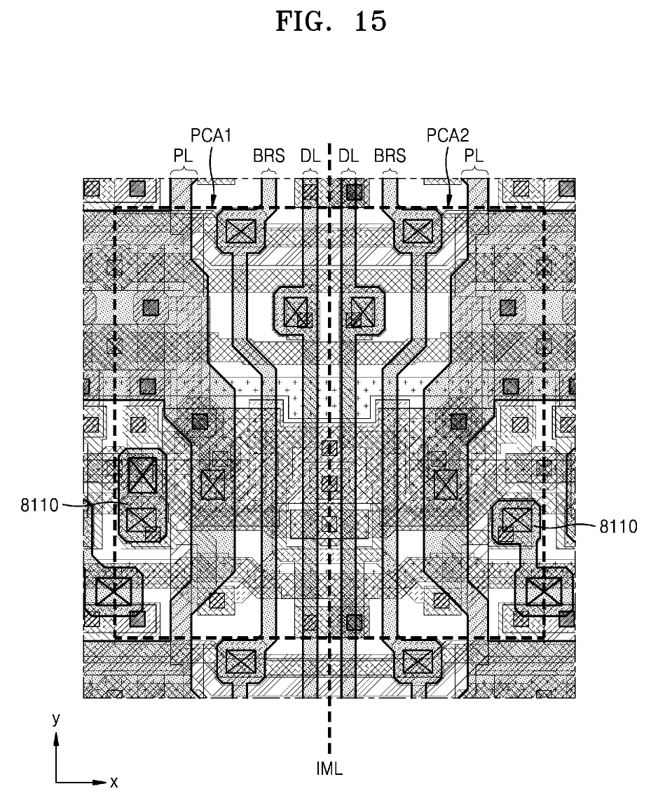

The third connection electrode 7130 may overlap the electrode voltage line 4110 described with reference to FIG. 11. The third connection electrode 7130 may be shared between the first and second pixel circuit areas PCA1 and PCA2. The third connection electrode 7130 may extend substantially in the first direction (e.g., x-axis direction), or may have an isolated shape without extending in the first direction (e.g., x-axis direction). The third connection electrode 7130 may be electrically connected to (e.g., be in contact with) the electrode voltage line 4110 through the contact hole PCNT. The third connection electrode 7130 may electrically connect a driving voltage line PL to be described below with reference to FIG. 15 and the electrode voltage line 4110 to each other.

The fourth connection electrode 7140 may electrically connect the bias voltage line VBL described with reference to FIG. 13 and the eighth semiconductor layer A8 of the first semiconductor pattern 2100 (see FIG. 9) to each other. The fourth connection electrode 7140 may be in contact with the bias voltage line VBL and the eighth semiconductor layer A8 through the contact holes OCNT and PCNT (see FIG. 13), respectively.

The fifth connection electrode 7150 may be electrically connected to the second semiconductor layer A2 of the first semiconductor pattern 2100 (see FIG. 9) through the contact hole PCNT (see FIG. 13). The fifth connection electrode 7150 may electrically connect a data line DL to be described below with reference to FIG. 15 and the second semiconductor layer A2 to each other.

The sixth connection electrode 7160 may be electrically connected to (e.g., be in direct contact with) the sixth semiconductor layer A6 of the first semiconductor pattern 2100 (see FIG. 9) through the contact hole PCNT (see FIG. 13).

The electrode initialization voltage line VAL may extend substantially in the first direction (e.g., x-axis direction). The electrode initialization voltage line VAL may be electrically connected to the seventh semiconductor layer A7 of the first semiconductor pattern 2100 (see FIG. 9) through the contact hole PCNT (see FIG. 13). The horizontal wiring HBRS may extend in the first direction (e.g., x-axis direction).

A sixth insulating layer 113 may be arranged on the bridge electrode 7110, the second connection electrode 7120, the third connection electrode 7130, the fourth connection electrode 7140, the fifth connection electrode 7150, the sixth connection electrode 7160, the electrode initialization voltage line VAL, and the horizontal wiring HBRS. The sixth insulating layer 113 may include an organic insulating material such as benzocyclobutene (BCB), polyimide, or hexamethyldisiloxane (HMDSO).

Via contact holes VCNT may be formed in the first and second pixel circuit areas PCA1 and PCA2. The via contact holes VCNT may penetrate (or pass through) the sixth insulating layer 113. The via contact holes VCNT, which are respectively arranged the first and second pixel circuit areas PCA1 and PCA2, may be substantially symmetrical with respect to the imaginary boundary line IML. The via contact holes VCNT may overlap the third connection electrode 7130, the fifth connection electrode 7150, the sixth connection electrode 7160, and the horizontal wiring HBRS, which have described with reference to FIG. 14.

Referring to FIGS. 7 and 15, a driving voltage line PL, a data line DL, a vertical wiring BRS, and a seventh connection electrode 8110 may be arranged on the sixth insulating layer 113.

The driving voltage line PL may be electrically connected to the third connection electrode 7130 through the via contact holes VCNT (see FIG. 14). The driving voltage line PL may overlap the bridge electrode 7110 (see FIG. 14). The driving voltage line PL may overlap the channel regions and gate electrodes of the third and fourth transistors T3 and T4.

The data line DL may be electrically connected to the fifth connection electrode 7150 through the via contact holes VCNT. The vertical wiring BRS may be electrically connected to the horizontal wiring HBRS through the via contact holes VCNT. The seventh connection electrode 8110 may be electrically connected to the sixth connection electrode 7160 through the via contact holes VCNT. The sixth semiconductor layer A6 may be electrically connected to a pixel electrode 210 through the sixth connection electrode 7160 and the seventh connection electrode 8110.

A seventh insulating layer 115 may be arranged on the driving voltage line PL, the data line DL, the vertical wiring BRS, and the seventh connection electrode 8110. The seventh insulating layer 115 may include an organic insulating material such as BCB, polyimide, or HMDSO.

The pixel electrode 210 may be arranged on the seventh insulating layer 115, as shown in FIG. 7. The pixel electrode 210 may be a reflective conductive layer. The pixel electrode 210 may include a reflective layer including Ag, Mg, Al, Pt, Pd, Au, Ni, Nd, Ir, Cr or a compound thereof, and a transparent or semi-transparent conductive layer positioned on the reflective layer. The transparent or semi-transparent conductive layer may include at least one selected from indium tin oxide (ITO), indium zinc oxide (IZO), zinc oxide (ZnOₓ: ZnO or ZnO₂), indium oxide (In₂O₃), indium gallium oxide (IGO), and aluminum zinc oxide (AZO).

A bank layer 119 may cover an edge portion of the pixel electrode 210, and may include a bank opening exposing a portion of the pixel electrode 210. The bank layer 119 may be an insulating layer, for example, an insulating layer including an organic material.

An emission layer 220 may overlap the pixel electrode 210 through the bank opening of the bank layer 119. For example, a common functional layer may be further arranged between the pixel electrode 210 and the emission layer 220, and/or between the emission layer 220 and a common electrode 230. The common functional layer may include at least one of a hole injection layer, a hole transport layer, an electron injection layer, and an electron transport layer. The common functional layer, like the common electrode 230, may be shared by a plurality of pixels.

The common electrode 230 may be shared by a plurality of light-emitting diodes. The common electrode 230 may be a transparent or semi-transparent electrode, and may include a metal thin film having a low work function, including Li, Ca, Al, Ag, Mg, or a compound thereof (e.g., LiF). For example, the common electrode 230 may further include a transparent conductive oxide (TCO) film, such as ITO, IZO, ZnO, ZnO₂, or In₂O₃ film, positioned on the metal thin film. The common electrode 230 may be formed as a single body over the entire display area DA (see FIG. 2) and cover entire the display area DA.

In an embodiment, a single emission layer may be interposed between the pixel electrode 210 and the common electrode 230, or a structure with a single emission layer and the above-described common functional layer are arranged between the pixel electrode 210 and the common electrode 230. In another embodiment, the emission layer 220 may have a tandem structure, which is a stacked structure of a plurality of sub-emission units, and each sub-emission unit may include an emission layer. For example, the emission layer 220 may have a stacked structure of N (where N is a positive integer of 2 or more) sub-emission units, and each sub-emission unit may have a structure in which a first common functional layer, an emission layer, and a second common functional layer are sequentially stacked. The first common functional layer and/or the second common functional layer of each sub-emission unit may be shared by a plurality of light-emitting diodes.

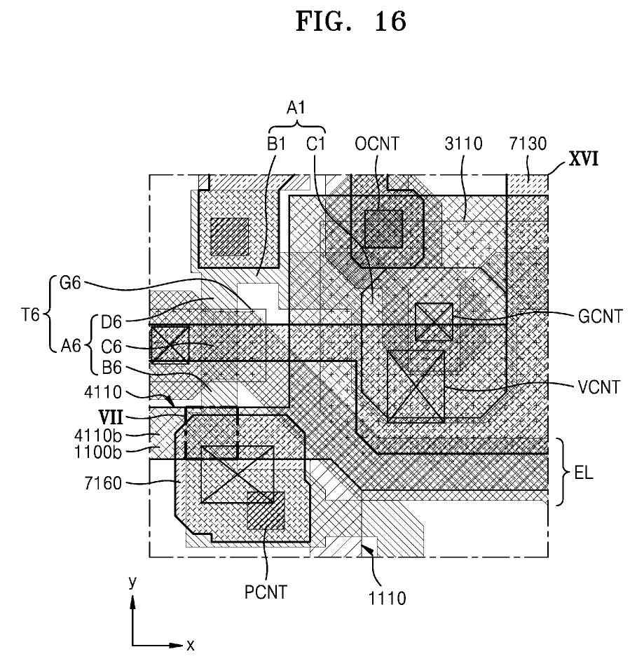

FIG. 16 is an enlarged cross-sectional view of a portion of the display panel 10 according to an embodiment, and some components are omitted for descriptive convenience. FIG. 16 may correspond to an enlarged view of region XVI of FIG. 14.

Referring to FIGS. 7 and 16, the first semiconductor layer A1 of the first transistor T1 may include the channel region C1 overlapping the first conductive layer 3110, and the first and second regions B1 and D1 respectively arranged on two sides (e.g., opposite sides) of the channel region C1. In an embodiment, the first region B1 of the first semiconductor layer A1 may be a drain region that is connected to the sixth semiconductor layer A6 as a single body (or single/integrated semiconductor pattern). The first region B1 of the first semiconductor layer A1 may be connected to the second region D6 of the sixth semiconductor layer A6 as a single body (or single/integrated semiconductor pattern). For descriptive convenience, the first region B1 of the first semiconductor layer A1 and the second region D6 of the sixth semiconductor layer A6 are distinguished in FIGS. 7 and 16, etc. However, the first region B1 of the first semiconductor layer A1 and the second region D6 of the sixth semiconductor layer A6 correspond to substantially the same region. For example, a portion (hereinafter, a first portion) of the first semiconductor pattern 2100 (see FIG. 9) that corresponds to a space between the channel region C1 of the first semiconductor layer A1 and the channel region C6 of the sixth semiconductor layer A6 may be referred to as the first region B1 of the first semiconductor layer A1 and the second region D6 of the sixth semiconductor layer A6.

The first portion of the first semiconductor pattern 2100 (see FIG. 9) may not overlap the branch portion 4110b of the electrode voltage line 4110, which extends in the first direction (e.g., x-axis direction). In an embodiment, the branch portion 4110b of the electrode voltage line 4110, which extends in the first direction (e.g., x-axis direction), may overlap a second portion of the first semiconductor pattern 2100 (see FIG. 9) (e.g., the first region B6 of the sixth semiconductor layer A6), which corresponds to a space between the channel region C6 of the sixth semiconductor layer A6 and a connection point (or contact portion) between the sixth semiconductor layer A6 and the sixth connection electrode 7160.

In a comparative example, when the first portion of the first semiconductor pattern 2100 (see FIG. 9) overlaps the branch portion 4110b, a black voltage (Vblack) corresponding to black gradation may be increased due to the parasitic capacitance between the first portion and the branch portion 4110b, thus increasing power consumption, and/or reddish black may be expressed when expressing black at low gradation. However, according to the above-described embodiment, by preventing or minimizing the parasitic capacitance between the first portion and the branch portion 4110b, a black voltage (Vblack) may be reduced, thus reducing power consumption, and/or expression of reddish black may be prevented or reduced.

In some embodiments, when the third connection electrode 7130 having the same voltage level as the electrode voltage line 4110 extends substantially in the first direction (e.g., x-axis direction), the third connection electrode 7130 may not overlap the first portion of the first semiconductor pattern 2100 (see FIG. 9) described above, for example, a portion of the first semiconductor pattern 2100 (see FIG. 9) that corresponds to a space between the channel region C1 of the first semiconductor layer A1 and the channel region C6 of the sixth semiconductor layer A6.

The sixth connection electrode 7160 on the sixth semiconductor layer A6 may overlap the sixth semiconductor layer A6, and may be connected to (e.g., be in direct contact with) the first region B6 of the sixth semiconductor layer A6 through the contact hole PCNT. An overlapping area between the sixth semiconductor layer A6 and the sixth connection electrode 7160 may overlap the branch portion 4110b of the electrode voltage line 4110 and the branch portion 1100b of the lower conductive layer 1100. Referring to region VII of FIG. 7, which is a cross-sectional structure corresponding to region VII of FIG. 16, the branch portion 1100b of the lower conductive layer 1100, a portion (e.g., the first region B6) of the sixth semiconductor layer A6, the branch portion 4110b of the electrode voltage line 4110, and the sixth connection electrode 7160 may overlap each other, and the capacitance may be induced between adjacent layers. For example, the capacitance between the branch portion 1100b of the lower conductive layer 1100 and the first region B6 of the sixth semiconductor layer A6, the capacitance between the first region B6 of the sixth semiconductor layer A6 and the branch portion 4110b of the electrode voltage line 4110, and the capacitance between the branch portion 4110b of the electrode voltage line 4110 and the sixth connection electrode 7160 may increase the capacitance of the pixel electrode 210, which is an anode. Accordingly, a black voltage (Vblack) may be reduced, power consumption may be reduced, and expression of reddish black may be prevented or reduced.

The emission control line EL may not overlap the sixth connection electrode 7160, or may overlap the sixth connection electrode 7160 to have a minimum overlapping area, as shown in FIG. 16, thereby suppressing an increase in black voltage (Vblack) caused by cycle operation of an emission control signal. As shown in FIG. 16, the emission control line EL may not overlap a portion of the sixth semiconductor layer A6 that is electrically connected to the sixth connection electrode 7160, for example, the first region B6, or may overlap the portion of the sixth semiconductor layer A6 to have a minimum overlapping area, thereby suppressing an increase in black voltage (Vblack) caused by cycle operation of an emission control signal.

In an embodiment, the capacitance, which is caused by the overlap of the emission control line EL and the sixth connection electrode 7160, may be greater than zero (0) femto-Farad (fF) and less than or equal to about 1.5 fF (or may be in a range of 0 fF to about 1.5 fF). The capacitance between the emission control line EL and a portion (e.g., the first region B6) of the sixth semiconductor layer A6 may be greater than 0 fF and less than or equal to about 1.5 fF (or may be in a range of about 0 fF to about 1.5 fF), not only when the emission control line EL and the portion (e.g., the first region B6) of the sixth semiconductor layer A6 overlap with a minimum area but also when the emission control line EL and the portion (e.g., the first region B6) of the sixth semiconductor layer A6 do not overlap, due to the close proximity.

According to one or more embodiments as described above, a display panel capable of displaying high-quality images, and an electronic apparatus including the display panel may be implemented. However, the scope of the disclosure is not limited to the above effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate;
a driving transistor comprising a driving semiconductor layer on the substrate;
a first switching transistor comprising a first switching semiconductor layer;
a light-emitting diode connected to the driving transistor through the first switching transistor;
a first conductive layer overlapping a channel region of the driving semiconductor layer in plan view and comprising a driving gate electrode of the driving transistor;
an electrode voltage line on the first conductive layer and comprising a main portion and a branch portion, the main portion overlapping the first conductive layer in plan view, and the branch portion extending from the main portion in a first direction; and
a driving voltage line extending in a second direction intersecting the first direction, and connected to the electrode voltage line,
wherein the driving semiconductor layer and the first switching semiconductor layer are integrally connected as a single semiconductor pattern, and a portion of the single semiconductor pattern between the channel region of the driving semiconductor layer and a channel region of the first switching semiconductor layer does not overlap the branch portion of the electrode voltage line in plan view.

2. The display panel of claim 1, further comprising:
a first connection electrode connected to the first switching semiconductor layer and being, in a cross-sectional view, between the first switching semiconductor layer and a pixel electrode of the light-emitting diode,
wherein, in plan view, the branch portion of the electrode voltage line overlaps a portion of the first switching semiconductor layer that is between the channel region of the first switching semiconductor layer and a contact portion between the first switching semiconductor layer and the first connection electrode.

3. The display panel of claim 2, wherein a portion of the first connection electrode overlaps the portion of the first switching semiconductor layer and a portion of the branch portion of the electrode voltage line in plan view.

4. The display panel of claim 2, further comprising:
an emission control line connected to a gate electrode of the first switching transistor,
wherein each of a capacitance between the emission control line and the first connection electrode and a capacitance between the emission control line and the portion of the first switching semiconductor layer is in a range of about 0 femto-Farad (fF) to about 1.5 fF.

5. The display panel of claim 4, wherein, in plan view, the emission control line does not overlap the portion of the first switching semiconductor layer.

6. The display panel of claim 2, further comprising:
a lower conductive layer below the driving semiconductor layer and comprising a main portion and a first branch portion, the main portion of the lower conductive layer overlapping the first conductive layer in plan view, and the first branch portion of the lower conductive layer extending from the main portion of the lower conductive layer in the first direction,
wherein the first branch portion of the lower conductive layer overlaps the branch portion of the electrode voltage line in plan view, and the portion of the first switching semiconductor layer is, in a cross-sectional view, between the first branch portion of the lower conductive layer and the branch portion of the electrode voltage line.

7. The display panel of claim 6, further comprising:
a second switching semiconductor layer in a different layer from the driving semiconductor layer; and
a bridge electrode connecting the first conductive layer and the second switching semiconductor layer.

8. The display panel of claim 7, wherein the lower conductive layer further comprises a second branch portion extending from the main portion of the lower conductive layer in the second direction,
the bridge electrode overlaps the second branch portion in plan view, and
the driving voltage line overlaps the bridge electrode in plan view.

9. The display panel of claim 6, wherein the lower conductive layer has a constant voltage level.

10. The display panel of claim 9, further comprising:
a second connection electrode being, in a cross-sectional view, between the electrode voltage line and the driving voltage line,
wherein the second connection electrode is connected to the electrode voltage line through a contact hole formed in an insulating layer between the electrode voltage line and the second connection electrode, and the driving voltage line is connected to the second connection electrode through a contact hole formed in an insulating layer between the driving voltage line and the second connection electrode, and
the second connection electrode extends in the first direction, and does not overlap the portion of the single semiconductor pattern in plan view.

11. An electronic apparatus comprising:
a substrate;
a first semiconductor pattern comprising silicon, the first semiconductor pattern comprising a driving semiconductor layer of a driving transistor and a first switching semiconductor layer of a first switching transistor;
a lower conductive layer between the substrate and the first semiconductor pattern;
a first conductive layer on the first semiconductor pattern and overlapping a channel region of the driving semiconductor layer in plan view;
an electrode voltage line on the first conductive layer and comprising a main portion and a branch portion, the main portion overlapping the first conductive layer in plan view, and the branch portion extending from the main portion in a first direction;
a driving voltage line extending in a second direction intersecting the first direction, and connected to the electrode voltage line;
a first connection electrode connected to the first switching semiconductor layer; and
a light-emitting diode comprising a pixel electrode on the first connection electrode and connected to the first connection electrode, an emission layer on the pixel electrode, and a common electrode on the emission layer,
wherein a first portion of the first semiconductor pattern between the channel region of the driving semiconductor layer and a channel region of the first switching semiconductor layer does not overlap the branch portion of the electrode voltage line in plan view.

12. The electronic apparatus of claim 11, wherein, in plan view, the branch portion of the electrode voltage line overlaps a second portion of the first semiconductor pattern that is between the channel region of the first switching semiconductor layer and a contact portion between the first switching semiconductor layer and the first connection electrode.

13. The electronic apparatus of claim 12, wherein a portion of the first connection electrode overlaps the second portion of the first semiconductor pattern and a portion of the branch portion of the electrode voltage line in plan view.

14. The electronic apparatus of claim 12, further comprising:
an emission control line connected to a gate electrode of the first switching transistor,
wherein, in plan view, the emission control line does not overlap the second portion of the first semiconductor pattern.

15. The electronic apparatus of claim 14, wherein a capacitance between the emission control line and the first connection electrode is in a range of about 0 femto-Farad (fF) to about 1.5 fF, and
a capacitance between the emission control line and the second portion of the first semiconductor pattern is in a range of about 0 fF to about 1.5 fF.

16. The electronic apparatus of claim 12, wherein the lower conductive layer comprises a main portion overlapping the first conductive layer in plan view and a first branch portion extending from the main portion of the lower conductive layer in the first direction,
wherein the first branch portion of the lower conductive layer overlaps the branch portion of the electrode voltage line in plan view, and the second portion of the first semiconductor pattern is, in a cross-sectional view, between the first branch portion of the lower conductive layer and the branch portion of the electrode voltage line.

17. The electronic apparatus of claim 11, further comprising:
a second semiconductor pattern in a different layer from the first semiconductor pattern and comprising an oxide semiconductor; and
a bridge electrode connecting the first conductive layer and the second semiconductor pattern.

18. The electronic apparatus of claim 17, wherein the lower conductive layer comprises a main portion overlapping the first conductive layer in plan view and a second branch portion extending from the main portion of the lower conductive layer in the second direction,
wherein the bridge electrode overlaps the second branch portion of the lower conductive layer in plan view, and
the driving voltage line overlaps the bridge electrode in plan view.

19. The electronic apparatus of claim 11, wherein the lower conductive layer has a constant voltage level.

20. The electronic apparatus of claim 11, further comprising a second connection electrode being, in a cross-sectional view, between the electrode voltage line and the driving voltage line,
wherein the second connection electrode is connected to the electrode voltage line through a contact hole formed in an insulating layer between the electrode voltage line and the second connection electrode, and the driving voltage line is connected to the second connection electrode through a contact hole formed in an insulating layer between the driving voltage line and the second connection electrode, and
the second connection electrode extends in the first direction, and does not overlap the first portion of the first semiconductor pattern in plan view.
